(19) United States
(12) Patent Application Publication
(10) Pub. No.: US 2023/0027391 A1
(43) Pub. Date: Jan. 26, 2023

(54) DISPLAY DEVICE

(71) Applicant: SAMSUNG DISPLAY CO., LTD., Yongin-si (KR)

(72) Inventors: Na Hyeon CHA, Yongin (KR); Dong Hee SHIN, Asan-si (KR); Min Kyu WOO, Seoul (KR)

(21) Appl. No.: 17/705,024

(22) Filed: Mar. 25, 2022

(30) Foreign Application Priority Data
Jul. 22, 2021 (KR) 10-2021-0096260

(51) Int. Cl. H01L 25/16; H01L 27/12; H01L 23/00

(52) U.S. Cl. CPC H01L 25/167; H01L 24/03; H01L 24/05; H01L 24/82; H01L 27/124; H01L 27/1288; H01L 24/24; H01L 24/25; H01L 2224/245; H01L 2224/03466; H01L 2224/03622; H01L 2224/05073; H01L 2224/05558; H01L 2224/05562; H01L 2224/05573; H01L 2224/05624; H01L 2224/05686; H01L 2224/24051; H01L 2224/24147; H01L 2224/25175; H01L 2224/82106; H01L 2924/0549; H01L 2924/01013

(57) ABSTRACT

A display device is provided. The display device comprising: a substrate including a display area and a pad area, a first conductive layer disposed on the substrate and including a first signal line disposed in the display area, a buffer layer disposed on the first conductive layer, a semiconductor layer disposed on the buffer layer in the display area, a gate insulating film disposed on the semiconductor layer, a second conductive layer disposed on the gate insulating film and including a gate electrode overlapping the semiconductor layer in the display area, a first electrode of a transistor disposed to overlap one side of the semiconductor layer in the display area and connected to the first signal line through a contact hole penetrating through the buffer layer and the gate insulating film, and a second electrode of the transistor disposed to overlap the other side of the semiconductor layer in the display area, a first pad disposed on the buffer layer in the pad area and exposed by a pad opening, a first insulating layer disposed on the second conductive layer and the first pad, and a light emitting element disposed on the first insulating layer in the display area, wherein the first pad is formed of the first conductive layer or the second conductive layer.

### CROSS-REFERENCE TO RELATED APPLICATION

This application claims priority to and the benefit of Korean Patent Application No. 10-2021-0096260 filed on Jul. 22, 2021 in the Korean Intellectual Property Office, the contents of which in its entirety are herein incorporated by reference.

### BACKGROUND

### 1. Field

The disclosure relates to a display device.

### 2. Description of the Related Art

The importance of display devices has increased with the development of multimedia. Accordingly, various types of display devices such as an organic light emitting display (OLED) and a liquid crystal display (LCD) have been used.

The display devices are devices displaying images, and include display panels such as organic light emitting display panels or liquid crystal display panels. The display panel may include a light emitting element, which may be a light emitting diode (LED). Examples of the light emitting diode include an organic light emitting diode (OLED) that uses an organic material as a light emitting material, an inorganic light emitting diode that uses an inorganic material as a light emitting material, and the like.

### SUMMARY

Aspects of the disclosure provide a display device including a wiring pad having high reliability.

Aspects of the disclosure also provide a method of manufacturing a display device having improved process efficiency.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device includes: a substrate including a display area and a pad area; a first conductive layer disposed on the substrate and including a first signal line disposed in the display area; a buffer layer disposed on the first conductive layer; a semiconductor layer disposed on the buffer layer in the display area; a gate insulating film disposed on the semiconductor layer; a second conductive layer disposed on the gate insulating film and including a gate electrode overlapping the semiconductor layer in the display area, a first electrode of a transistor disposed to overlap one side of the semiconductor layer in the display area and connected to the first signal line through a contact hole penetrating through the buffer layer and the gate insulating film, and a second electrode of the transistor disposed to overlap the other side of the semiconductor layer in the display area; a first pad disposed on the buffer layer in the pad area and exposed by a pad opening; a first insulating layer disposed on the second conductive layer and the first pad; and a light emitting element disposed on the first insulating layer in the display area, wherein the first pad is formed of the first conductive layer or the second conductive layer.

According to another aspect of the disclosure, a display device includes: a substrate including a display area and a pad area; a first conductive layer disposed on the substrate and including a first signal line disposed in the display area and a first pad disposed in the pad area; a buffer layer disposed on the first conductive layer; a semiconductor layer disposed on the buffer layer in the display area; a gate insulating film disposed on the semiconductor layer; a second conductive layer disposed on the gate insulating film and including a gate electrode overlapping the semiconductor layer in the display area, a first electrode of a transistor disposed to overlap one side of the semiconductor layer in the display area, and a second electrode of the transistor disposed to overlap the other side of the semiconductor layer in the display area; a first insulating layer disposed on the second conductive layer; a light emitting element disposed on the first insulating layer in the display area; a first contact electrode disposed in the display area and electrically connecting the transistor, the first electrode, and one end of the light emitting element to each other; and a pad electrode disposed in the pad area and electrically connected to the first pad through a pad opening penetrating through the buffer layer and the first insulating layer, wherein the first electrode of the transistor is electrically connected to the first signal line through a contact hole penetrating through the buffer layer and the gate insulating film.

Detailed contents of other embodiments are described in a detailed description and are illustrated in the drawings.

With the display device according to one or more embodiments, the number of mask processes is minimized, and direct contact between a conductive layer constituting a wiring pad and a reactive material is suppressed, such that reliability of the wiring pad may be improved.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to one or more embodiments;

FIG. 2 is a schematic layout diagram illustrating wirings included in the display device according to one or more embodiments;

FIG. 3 is a schematic plan layout diagram illustrating one pixel of the display device according to one or more embodiments;

FIG. 4 is a cross-sectional view of the display device according to one or more embodiments;

FIG. 5 is a schematic perspective view of a light emitting element according to one or more embodiments;

FIG. 6 is an enlarged cross-sectional view of the display device according to one or more embodiments;

FIGS. 7 to 19 are cross-sectional views illustrating processes of manufacturing the display device of FIG. 4;

FIG. 20 is a cross-sectional view of a display device according to one or more other embodiments;

FIG. 21 is a cross-sectional view of a display device according to still one or more other embodiments;

FIG. 22 is a cross-sectional view of a display device according to still one or more other embodiments;

FIGS. 23 to 32 are cross-sectional views illustrating processes of manufacturing the display device of FIG. 22;

FIG. 33 is a cross-sectional view of a display device according to still one or more other embodiments; and

FIG. 34 is a cross-sectional view of a display device according to still one or more other embodiments.

### DETAILED DESCRIPTION

The present disclosure will now be described more fully hereinafter with reference to the accompanying drawings, in which embodiments of the present disclosure are shown. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Hereinafter, embodiments of the disclosure will be described with reference to the drawings.

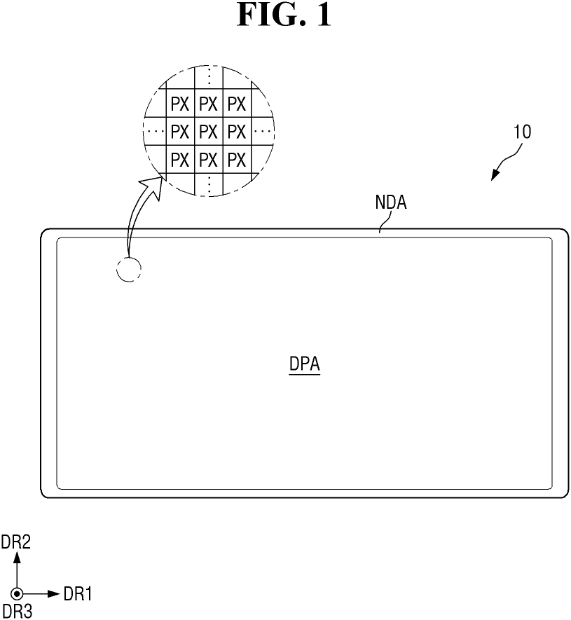

FIG. 1 is a schematic plan view of a display device according to one or more embodiments.

Referring to FIG. 1, a display device 10 displays a moving image or a still image. The display device 10 may refer to all electronic devices that provide display screens. For example, televisions, laptop computers, monitors, billboards, the Internet of Things (IoT), mobile phones, smartphones, tablet personal computers (PCs), electronic watches, smartwatches, watch phones, head mounted displays, mobile communication terminals, electronic organizers, electronic books, portable multimedia players (PMPs), navigation devices, game machines, digital cameras, camcorders, and the like, which provide display screens, may be included in the display device 10.

The display device 10 includes a display panel providing a display screen. Examples of the display panel include an inorganic light emitting diode display panel, an organic light emitting display panel, a quantum dot light emitting display panel, a plasma display panel, a field emission display panel, and the like. Hereinafter, a case where an inorganic light emitting diode display panel is applied as an example of the display panel will be described by way of example, but the disclosure is not limited thereto, and the same technical idea may be applied to other display panels if applicable.

Hereinafter, a first direction DR1, a second direction DR2, and a third direction DR3 are defined in the drawings of one or more embodiments for describing the display device 10. The first direction DR1 and the second direction DR2 may be directions perpendicular to each other in one plane. The third direction DR3 may be a direction perpendicular to the plane in which the first direction DR1 and the second direction DR2 are positioned. The third direction DR3 is perpendicular to each of the first direction DR1 and the second direction DR2. In one or more embodiments for describing the display device 10, the third direction DR3 refers to a thickness direction (or a display direction) of the display device 10.

The display device 10 may have a rectangular shape, in plan view, in which a side extending in the first direction DR1 is longer than a side extending in the second direction DR2, and which includes long sides and short sides. A corner portion where the long side and the short side of the display device 10 meet in plan view may be right-angled, but is not limited thereto, and may also have a rounded curved shape. A shape of the display device 10 is not limited to those described above, and may be variously modified. For example, the shape of the display device 10 may also be other shapes such as a square shape, a quadrangular shape with rounded corners (vertices), other polygonal shapes, and a circular shape in plan view.

A display surface of the display device 10 may be disposed on one side of the display device 10 in the third direction DR3, which is the thickness direction. In embodiments for describing the display device 10, unless otherwise stated, “upper portion” is one side in the third direction DR3 and refers to the display direction, and “upper surface” refers to a surface facing one side in the third direction DR3. In addition, “lower portion” is the other side in the third direction DR3 and refers to a direction opposite to the display direction, and “lower surface” refers to a surface facing the other side in the third direction DR3. In addition, “left”, “right”, “upper”, and “lower” refer to directions when the display device 10 is viewed in plan view. For example, “right side” refers to one side in the first direction DR1, “left side” refers to the other side in the first direction DR1, “upper side” refers to one side in the second direction DR2, and “lower side” refers to the other side in the second direction DR2.

The display device 10 may include a display area DPA and a non-display area NDA. The display area DPA is an area in which a screen may be displayed, and the non-display area NDA is an area in which a screen is not displayed.

A shape of the display area DPA may follow the shape of the display device 10. For example, the shape of the display area DPA may have a rectangular shape in plan view, similar to the overall shape of the display device 10. The display area DPA may occupy substantially the center of the display device 10.

The display area DPA may include a plurality of pixels PX. The plurality of pixels PX may be arranged in a matrix direction. A shape of each pixel PX may be a rectangular or square shape in plan view. In one or more embodiments, each pixel PX may include a plurality of light emitting elements made of inorganic particles.

The non-display area NDA may be disposed around the display area DPA. The non-display area NDA may entirely or partially surround the display area DPA. The non-display areas NDA may constitute a bezel of the display device 10.

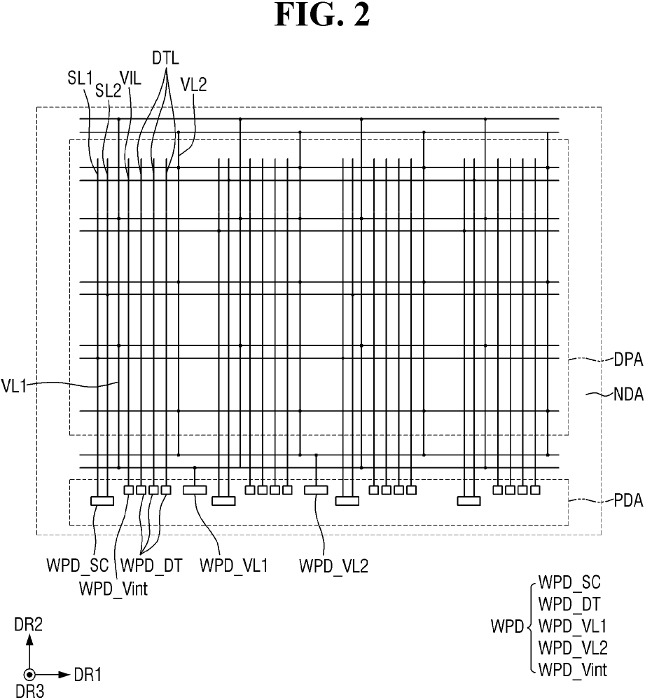

FIG. 2 is a schematic layout diagram illustrating wirings included in the display device according to one or more embodiments.

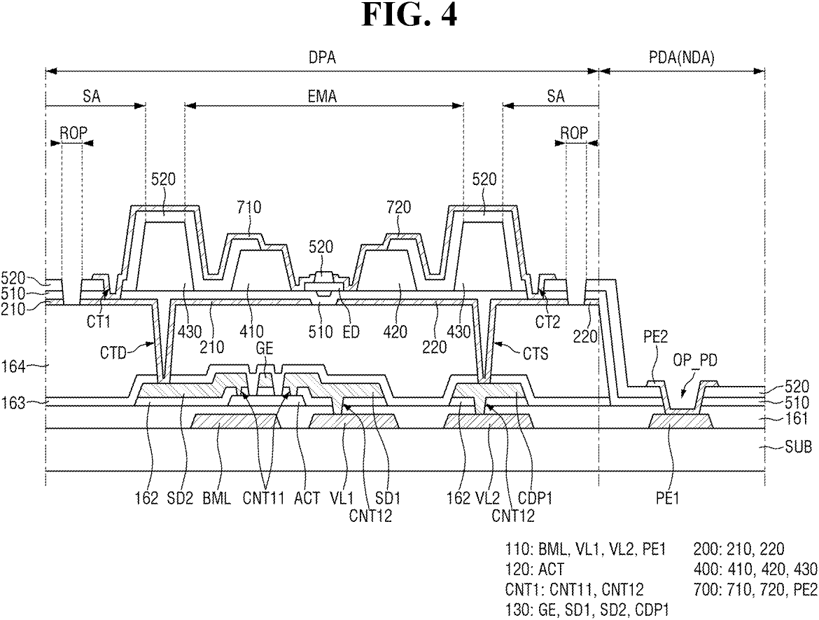

Referring to FIG. 2, the display device 10 may include a plurality of wirings. The plurality of wirings may include first voltage lines VL1, second voltage lines VL2, data lines DTL, first scan lines SL1, second scan lines SL2, and initialization voltage lines VIL. In addition, although not illustrated in FIG. 2, other wirings may be further disposed in the display device 10. The plurality of wirings included in the display device 10 may be formed of a first conductive layer 110 or a second conductive layer 130 of a circuit element layer to be described later (e.g., see FIG. 4).

Meanwhile, in the specification, the term “connection” may mean not only that any one member is connected to another member through physical contact with another member, but also that any one member is connected to another member through the other member. In addition, it may be understood that any one portion and another portion as one integrated member are interconnected due to the integrated member. Furthermore, a connection between any one member and another member may be interpreted as the meaning including an electrical connection through the other member in addition to a connection through direct contact therebetween.

The first and second scan lines SL1 and SL2 may include portions extending in the first direction DR1, respectively. The first and second scan lines SL1 SL2 may further include portions extending in the second direction DR2, respectively. The portions of the first and second scan lines SL1 and SL2 extending in the first direction DR1 and the portions of the first and second scan lines SL1 and SL2 extending in the second direction DR2 may be formed of conductive layers disposed on different layers. One ends of the first and second scan lines SL1 and SL2 extending in the second direction DR2 may be connected to scan pads WPD_SC connected to a scan driver. The first and second scan lines SL1 and SL2 may be disposed to extend from a pad area PDA disposed in the non-display area NDA to the display area DPA.

A plurality of data lines DTL may extend in the second direction DR2. In the plurality of data lines DTL, three data lines DTL form a group and are disposed to neighbor and be adjacent to each other. The respective data lines DTL may be disposed to extend from the pad area PDA disposed in the non-display area NDA to the display area DPA.

The initialization voltage lines VIL may extend in the second direction DR2. The initialization voltage lines VIL may be disposed to be spaced apart from the data lines DTL. The initialization voltage lines VIL may be disposed to extend from the pad area PDA disposed in the non-display area NDA to the display area DPA.

The first voltage lines VL1 and the second voltage lines VL2 may include portions extending in the second direction DR2. The first voltage lines VL1 and the second voltage lines VL2 may further include portions extending in the first direction DR1. The portions of the first and second voltage lines VL1 and VL2 extending in the first direction DR1 and the portions of the first and second voltage lines VL1 and VL2 in the second direction DR2 may be formed of conductive layers disposed on different layers. The first voltage lines VL1 and the second voltage lines VL2 may have a mesh structure, but are not limited thereto.

The data line DTL, the initialization voltage line VIL, the first voltage line VL1, and the second voltage line VL2 may be electrically connected to at least one wiring pad WPD. Each wiring pad WPD may be disposed in the pad area PDA included in the non-display area NDA. The pad area PDA may be disposed in the non-display area NDA disposed adjacent to a first long side (lower side in FIG. 2) of the display device 10. However, a position of the pad area PDA is not limited thereto, and may be variously modified.

Wiring pads (hereinafter, referred to as “scan pads”) WPD_SC of the first and second scan lines SL1 and SL2, wiring pads (hereinafter, referred to as “data pads”) WPD_DT of the data lines DTL, wiring pads (hereinafter, referred to as “initialization voltage pads”) WPD_Vint of the initialization voltage lines VIL, a wiring pad (hereinafter, referred to as a “first voltage pad”) WPD_VL1 of the first voltage lines VL1 and a wiring pad (hereinafter, referred to as a “second voltage pad”) WPD_VL2 of the second voltage lines VL2 may be disposed in the pad area PDA disposed below the display area DPA. An external device may be mounted on the wiring pad WPD. The external device may be mounted on the wiring pad WPD through an anisotropic conductive film, ultrasonic bonding, or the like. Meanwhile, it has been illustrated in FIG. 2 that the pad area PDA in which a plurality of wiring pads WPD are disposed is disposed below the display area DPA, but the disclosure is not limited thereto.

Each pixel PX of the display device 10 includes a pixel driving circuit. The above-described wirings may apply driving signals to the respective pixel driving circuits while passing through the respective pixels PX or around the respective pixels PX. The pixel driving circuit may include a transistor and a capacitor. The numbers of transistors and capacitors in each pixel driving circuit may be variously modified.

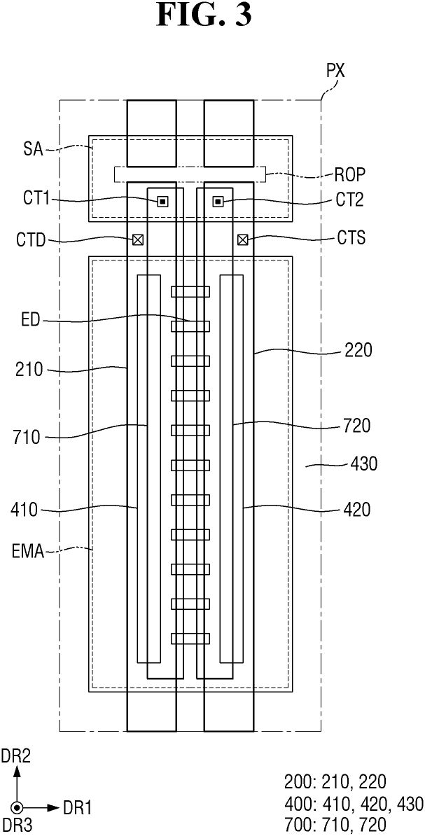

FIG. 3 is a schematic plan layout diagram illustrating one pixel of the display device according to one or more embodiments.

Referring to FIG. 3, one pixel PX of the display device 10 according to one or more embodiments may include a plurality of light emitting elements ED, a first layer 200, a second layer 700, and a bank layer 400. The plurality of light emitting elements ED, the first layer 200 and the second layer 700 may be disposed in each pixel PX.

Each pixel PX of the display device 10 may include an emission area EMA (e.g., see FIG. 4) and a non-emission area. The emission area EMA may be defined as an area in which light emitted from the light emitting elements ED is emitted, and the non-emission area may be defined as an area in which the light emitted from the light emitting elements ED does not arrive and thus, the light is not emitted.

The emission area EMA may include an area in which the light emitting elements ED are disposed and an area adjacent thereto. In addition, the emission area EMA may further include an area in which the light emitted from the light emitting elements ED is reflected or refracted by other members and then emitted.

Each pixel PX may further include a sub-area SA disposed in the non-emission area. The light emitting elements ED may not be disposed in the sub-area SA. The sub-area SA may be disposed on one side or the other side of the emission area EMA in the second direction DR2 in plan view in one pixel PX. For example, the sub-area SA may be disposed on an upper side of the emission area EMA in plan view in one pixel PX. The sub-area SA may be disposed between emission areas EMA of pixels PXs neighboring to each other in the second direction DR2.

The sub-area SA may include an area in which a first electrode 210 and a second electrode 220 of the first layer 200 are electrically connected to a first contact electrode 710 and a second contact electrode 720 of the second layer 700 through contact parts CT1 and CT2, respectively.

The sub-area SA may include a separation part ROP. The separation part ROP may be an area in which the first layers 200 included in the respective pixels PX neighboring to each other along the second direction DR2 are separated from each other.

The first layer 200 may be disposed over the emission area EMA and the sub-area SA. The first layer 200 may include a plurality of electrodes extending in the second direction DR2 and spaced apart from each other in the first direction DR1. For example, the first layer 200 may include the first electrode 210 and the second electrode 220.

The first electrode 210 and the second electrode 220 may be disposed over the emission area EMA and the sub-area SA of each pixel PX, but may be spaced apart from a first electrode 210 and a second electrode 220 included in a pixel PX neighboring in the second direction DR2, respectively, in the separation part ROP positioned in the sub-area SA.

The first electrode 210 and the second electrode 220 separated in the separation part ROP of each pixel PX may be formed after a process for aligning a plurality of light emitting elements ED among processes of manufacturing the display device 10. For example, in the process for aligning a plurality of light emitting elements ED among the processes of manufacturing the display device 10, an electric field may be generated using alignment lines extending in the second direction DR2, and the plurality of light emitting elements ED may be aligned by receiving a dielectrophoretic force by the electric field generated on the alignment lines. After the process for aligning the light emitting elements ED is performed, a plurality of alignment lines are separated in the separation part ROP positioned in the sub-area SA of each pixel PX, such that the first electrode 210 and the second electrode 220 separated in the separation part ROP of each pixel PX may be formed, as illustrated in FIG. 3.

The first electrode 210 may be electrically connected to a circuit element layer to be described later through a first electrode contact hole CTD. The second electrode 220 may be electrically connected to a circuit element layer to be described later through a second electrode contact hole CTS.

The first electrode 210 is electrically connected to the circuit element layer through the first electrode contact hole CTD, and the second electrode 220 is electrically connected to the circuit element layer through the second electrode contact hole CTS, such that an electrical signal applied to the circuit element layer may be transferred to both ends of the light emitting element ED via the first electrode 210 and the second electrode 220, respectively.

Meanwhile, it has been illustrated in FIG. 3 that the first and second electrode contact holes CTD and CTS are disposed to overlap a first bank 430 of the bank layer 400 in the third direction DR3, but positions of the first and second electrode contact holes CTD and CTS are not limited thereto.

The bank layer 400 may include a first sub-bank 410, a second sub-bank 420, and the first bank 430 spaced apart from each other.

The first bank 430 may be disposed across boundaries between the respective pixels PX to divide neighboring pixels PX, and may divide the emission area EMA and the sub-area SA. The first bank 430 may be disposed in a lattice pattern in plan view by including portions extending in the first direction DR1 and the second direction DR2 in plan view.

As described later, the first bank 430 may be formed to have a greater height than the first and second sub-banks 410 and 420, to allow ink (in which the plurality of light emitting elements ED are dispersed) not to be mixed in adjacent pixels PX and to be jetted into the emission area EMA in an inkjet printing process for aligning the light emitting elements ED among the processes of manufacturing the display device 10. That is, the first bank 430 may be disposed to surround the sub-area SA and the emission area EMA so as to divide the sub-area SA and the emission area EMA, and serve to guide the ink in which the plurality of light emitting elements ED are dispersed so that the ink is not jetted into the sub-area SA and is stably jetted into the emission area EMA, in the inkjet printing process for aligning the plurality of light emitting elements ED.

The first sub-bank 410 and the second sub-bank 420 may be disposed in the emission area EMA partitioned by the first bank 430. Each of the first sub-bank 410 and the second sub-bank 420 may extend in the second direction DR2. The first sub-bank 410 and the second sub-bank 420 may be spaced apart from each other in the first direction DR1 in the emission area EMA.

The first sub-bank 410 may be disposed to overlap the first electrode 210 in the third direction DR3 in the emission area EMA, and the second sub-bank 420 may be disposed to overlap the second electrode 220 in the third direction DR3 in the emission area EMA.

The plurality of light emitting elements ED may be disposed in the emission area EMA. The plurality of light emitting elements ED may not be disposed in the sub-area SA. As described above, the first bank 430 is formed to partition the sub-area SA of each pixel PX, such that the ink in which the plurality of light emitting elements ED are dispersed is jetted only into the emission area EMA, and thus, the plurality of light emitting elements ED may be disposed in the emission area EMA, but may not be disposed in the sub-area SA.

The plurality of light emitting elements ED may be disposed between the first sub-bank 410 and the second sub-bank 420 in the emission area EMA. Each of the plurality of light emitting elements ED may have a shape in which it extends in one direction, and an extension direction of each light emitting element ED may be substantially perpendicular to an extension direction of the first electrode 210 and the second electrode 220. However, the disclosure is not limited thereto, and the extension direction of the light emitting element ED may also be oblique to the extension direction of the first electrode 210 and the second electrode 220. The light emitting element ED may be aligned so that at least one of both ends thereof is put on the first electrode 210 or the second electrode 220 in an area in which the first sub-bank 410 and the second sub-bank 420 are spaced apart from and face each other.

The plurality of light emitting elements ED may be spaced apart from each other. The plurality of light emitting elements ED may be disposed to be spaced apart from each other along the second direction DR2 between the first sub-bank 410 and the second sub-bank 420. The plurality of light emitting elements ED may be aligned in one column between the first sub-bank 410 and the second sub-bank 420, and distances between the light emitting elements ED disposed adjacent to each other in the second direction DR2 may be random.

The second layer 700 may be disposed over the emission area EMA and the sub-area SA. The second layer 700 may include a plurality of contact electrodes. For example, the second layer 700 may include the first contact electrode 710 and the second contact electrode 720. The first contact electrode 710 and the second contact electrode 720 may extend in the second direction DR2, respectively, and may be spaced apart from each other in the first direction DR1.

The first contact electrode 710 may be disposed to overlap the first electrode 210 in the third direction DR3 in the emission area EMA and the sub-area SA of each pixel PX. The first contact electrode 710 may be disposed to overlap one ends of the plurality of light emitting elements ED in the emission area EMA.

The first contact electrode 710 may be in contact with the first electrode 210 through a first contact part CT1 in the sub-area SA, and may be in contact with one ends of the plurality of light emitting elements ED in the emission area EMA. The first contact electrode 710 may be in contact with each of one ends of the light emitting elements ED and the first electrode 210, such that one ends of the light emitting elements ED and the first electrode 210 may be electrically connected to each other via the first contact electrode 710. Meanwhile, it has been illustrated in FIG. 3 that that the first contact electrode 710 is in contact with the first electrode 210 in the sub-area SA, the disclosure is not limited thereto. For example, the first contact electrode 710 may also be in contact with the first electrode 210 in the emission area EMA of each pixel PX.

The second contact electrode 720 may be disposed to overlap the second electrode 220 in the third direction DR3 in the emission area EMA and the sub-area SA of each pixel PX. The second contact electrode 720 may be disposed to overlap the other ends of the plurality of light emitting elements ED in the emission area EMA.

The second contact electrode 720 may be in contact with the second electrode 220 through a second contact part CT2 in the sub-area SA, and may be in contact with the other ends of the plurality of light emitting elements ED in the emission area EMA. The second contact electrode 720 may be in contact with each of the other ends of the light emitting elements ED and the second electrode 220, such that the other ends of the light emitting elements ED and the second electrode 220 may be electrically connected to each other via the second contact electrode 720. Meanwhile, it has been illustrated in FIG. 3 that that the second contact electrode 720 is in contact with the second electrode 220 in the sub-area SA, the disclosure is not limited thereto. For example, the second contact electrode 720 may also be in contact with the second electrode 220 in the emission area EMA of each pixel PX.

FIG. 4 is a cross-sectional view of the display device according to one or more embodiments.

FIG. 4 illustrates cross sections of a portion of the display area DPA and a portion of the non-display area NDA together. Cross sections of the emission area EMA and the sub-area SA are illustrated as the cross section of the display area DPA, and a cross section of the pad area PDA is illustrated as the cross section of the non-display area NDA.

Referring to FIG. 4, the display device 10 may include a substrate SUB, and a semiconductor layer, a plurality of conductive layers, and a plurality of insulating layers disposed on the substrate SUB. The semiconductor layer, the conductive layers, and the insulating layers may constitute a circuit layer and a display element layer of the display device 10, respectively.

The substrate SUB may be a base substrate or a base member. The substrate SUB may be made of an insulating material such as glass, quartz, or a polymer resin. The substrate SUB may be a rigid substrate, but may also be a flexible substrate capable of being bent, folded, or rolled.

The circuit element layer may be disposed on the substrate SUB. The circuit element layer may include a first conductive layer 110, a buffer layer 161, a semiconductor layer 120, a gate insulating film 162, a second conductive layer 130, a passivation layer 163, and a via layer 164.

The first conductive layer 110 is disposed on the substrate SUB. The first conductive layer 110 may include a first voltage line VL1, a second voltage line VL2, a light blocking pattern BML, and a first pad PE1. That is, the first voltage line VL1, the second voltage line VL2, and the light blocking pattern BML disposed in the display area DPA and the first pad PE1 disposed in the pad area PDA may be formed of the first conductive layer 110. However, the disclosure is not limited thereto, and the data line DTL, the initialization voltage line VIL, or the first and second scan lines SL1 and SL2 extending in the second direction DR2 as described above may also be formed of the first conductive layer 110.

The first voltage line VL1 may overlap at least a portion of a drain electrode SD1 of a transistor to be described later in a thickness direction of the substrate SUB. The first voltage line VL1 may be electrically connected to the drain electrode SD1 of the transistor through a first contact hole CNT12. A high potential voltage (or a first source voltage) supplied to the transistor may be applied to the first voltage line VL1.

The second voltage line VL2 may overlap at least a portion of a first conductive pattern CDP1 in the thickness direction of the substrate SUB. The second voltage line VL2 may be electrically connected to the first conductive pattern CDP1 through a first contact hole CNT12. A low potential voltage (or a second source voltage), which is lower than the high potential voltage supplied to the first voltage line VL1, may be applied to the second voltage line VL2.

That is, the high potential voltage (or the first source voltage) supplied to the transistor may be applied to the first voltage line VL1, and the low potential voltage (or the second source voltage), which is lower than the high potential voltage supplied to the first voltage line VL1, may be applied to the second voltage line VL2.

The light blocking pattern BML may be disposed below a semiconductor pattern ACT of the transistor so as to cover at least a channel region of the semiconductor pattern ACT of the transistor. The light blocking pattern BML may be a light blocking layer serving to protect the semiconductor pattern ACT of the transistor from external light. However, the disclosure is not limited thereto, and the light blocking pattern BML may be omitted.

The first pad PE1 may be one of the wiring pads WPD of the plurality of wirings described above. For example, the first pad PE1 may be one of the first voltage pad WPD_VL1, the second voltage pad WPD_VL2, the data pad WPD_DT, or the initialization voltage pad WPD_Vint. For example, when the first pad PE1 is the wiring pad WPD of the first voltage line VL1, the first pad PE1 may be the first voltage pad WPD_VL1 provided at an end of the first voltage line VL1. The first pad PE1 may overlap a pad electrode PE2, which is a contact electrode of the wiring pad WPD to be described later, in the thickness direction of the substrate SUB.

In some embodiments, the first conductive layer 110 may include a material for blocking light. For example, the first conductive layer 110 may be formed of an opaque metal material blocking transmission of the light. In some other embodiments, the first conductive layer 110 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, the disclosure is not limited thereto. In one or more embodiments, the first conductive layer 110 may be formed as a Ti/Cu double film in which a titanium layer and a copper layer are stacked, but is not limited thereto.

The buffer layer 161 may be disposed on the first conductive layer 110. The buffer layer 161 may be disposed to cover the entire surface of the substrate SUB on which the first conductive layer 110 is disposed. The buffer layer 161 may be disposed in the display area DPA and the pad area PDA of the non-display area NDA. The buffer layer 161 may define first contact holes CNT1 exposing portions of the first conductive layer 110 together with the gate insulating film 162 in the display area DPA. The buffer layer 161 may define a pad opening OP_PD exposing the first pad PE1 together with a first insulating layer 510 and a second insulating layer 520 to be described later in the pad area PDA.

The buffer layer 161 may serve to protect a plurality of transistors from moisture permeating through the substrate SUB vulnerable to moisture permeation. The buffer layer 161 may include an inorganic insulating material such as silicon oxide (SiOx), silicon nitride (SiNx), or silicon oxynitride (SiOxNy).

The semiconductor layer 120 is disposed on the buffer layer 161. The semiconductor layer 120 may include the semiconductor pattern ACT of the transistor disposed in the display area DPA. The semiconductor pattern ACT of the transistor may be disposed to overlap the light blocking pattern BML as described above.

The semiconductor layer 120 may include polycrystalline silicon, single crystal silicon, an oxide semiconductor, or the like. In one or more embodiments, when the semiconductor layer 120 includes the polycrystalline silicon, the polycrystalline silicon may be formed by crystallizing amorphous silicon. When the semiconductor layer 120 includes the polycrystalline silicon, the semiconductor pattern ACT of the transistor may include a plurality of doped regions doped with impurities and a channel region between the plurality of doped regions. In one or more other embodiments, the semiconductor layer 120 may include an oxide semiconductor. The oxide semiconductor may be, for example, indium tin oxide (ITO), indium zinc oxide (IZO), indium gallium oxide (IGO), indium zinc tin oxide (IZTO), indium gallium zinc oxide (IGZO), indium gallium tin oxide (IGTO), indium gallium zinc tin oxide (IGZTO), or the like.

The gate insulating film 162 may be disposed on the buffer layer 161 on which the semiconductor layer 120 is disposed. The gate insulating film 162 may be formed in the same pattern as a second conductive layer 130 to be described later. Sidewalls of the gate insulating film 162 may be substantially aligned with sidewalls of the second conductive layer 130, but are not limited thereto. The gate insulating film 162 may be formed as multiple layers in which inorganic layers including at least one of inorganic materials such as silicon oxide (SiOx), silicon nitride (SiNx), and silicon oxynitride (SiOxNy) are alternately stacked.

The second conductive layer 130 may be disposed on the gate insulating film 162. The second conductive layer 130 may include a gate electrode GE, the drain electrode SD1, and a source electrode SD2 of the transistor, and the first conductive pattern CDP1 that are disposed in the display area DPA. In addition, the first scan line SL1 and the second scan line SL2 extending in the first direction DR1, the first voltage line and the second voltage line extending in the first direction DR1, or the like, as described above, may be formed of the second conductive layer 130.

The gate electrode GE may be disposed to overlap the channel region of the semiconductor pattern ACT in the third direction DR3, which is the thickness direction of the substrate SUB.

The drain electrode SD1 may be spaced apart from the gate electrode GE. The drain electrode SD1 may be in contact with and electrically connected to one end region of the semiconductor pattern ACT through a first contact hole CNT11 penetrating through the gate insulating film 162 and exposing one end region of the semiconductor pattern ACT. In addition, the drain electrode SD1 may be in contact with and electrically connected to the first voltage line VL1 through the first contact hole CNT12 penetrating through the gate insulating film 162 and the buffer layer 161 and exposing a partial region of the first voltage line VL1. One end region of the semiconductor pattern ACT and the first voltage line VL1 may be electrically connected to each other through the drain electrode SD1.

The source electrode SD2 may be spaced apart from the drain electrode SD1 and the gate electrode GE. The source electrode SD2 may be in contact with and electrically connected to the other end region of the semiconductor pattern ACT through a first contact hole CNT11 penetrating through the gate insulating film 162 and exposing the other end region of the semiconductor pattern ACT. Meanwhile, it has been illustrated in FIG. 4 that the source electrode SD2 is not in contact with the light blocking pattern BML disposed thereunder, but the disclosure is not limited thereto. For example, the source electrode SD2 may also be in contact with and electrically connected to the light blocking pattern BML disposed thereunder through a contact hole penetrating through the gate insulating film 162 and the buffer layer 161.

The first conductive pattern CDP1 may overlap the second voltage line VL2. The first conductive pattern CDP1 may be in contact with and electrically connected to the second voltage line VL2 through the first contact hole CNT12 penetrating through the gate insulating film 162 and the buffer layer 161 and exposing a partial region of the second voltage line VL2. The first conductive pattern CDP1 may be a connection pattern electrically connecting the second voltage line VL2 formed of the first conductive layer 110 and a second electrode 220 to be described later to each other.

As described later, the first contact hole CNT12 penetrating through the buffer layer 161 and the gate insulating film 162 and the first contact hole CNT11 penetrating through the gate insulating film 162 may be contact holes CNT1 simultaneously formed through a single mask process.

The second conductive layer 130 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof

The passivation layer 163 may be disposed on the buffer layer 161 on which the second conductive layer 130 is formed. The passivation layer 163 may serve to cover and protect the second conductive layer 130. The passivation layer 163 may include an inorganic insulating material such as silicon oxide (SiOx), silicon nitride (SiNx), or silicon oxynitride (SiOxNy).

The passivation layer 163 may be formed in the display area DPA, but may not be at least partially formed in the non-display area NDA. For example, the passivation layer 163 may be disposed in the display area DPA, but may not be disposed in at least the pad area PDA of the non-display area NDA. In one or more embodiments, the passivation layer 163 is not formed on the first pad PE1, and thus, may not overlap at least the first pad PE1 of the pad area PDA. The passivation layer 163 may be formed in the same pattern as the via layer 164. Sidewalls of the passivation layer 163 may be substantially aligned with sidewalls of the via layer 164. The sidewalls of the via layer 164 and the sidewalls of the passivation layer 163 defining the first and second electrode contact holes CTD and CTS may overlap and be aligned with each other.

The via layer 164 may be disposed on the passivation layer 163. The via layer 164 may be disposed in the display area DPA, but may not be disposed in at least the pad area PDA of the non-display area NDA. The via layer 164 may be disposed to cover an upper surface of the passivation layer 163 in the display area DPA. In one or more embodiments, the via layer 164 is not formed on the first pad PE1, and thus, may not overlap at least the first pad PE1 of the pad area PDA. As described above, in the display area DPA, a pattern of the via layer 164 may be the same as that of the passivation layer 163 disposed under the via layer 164. As described later, the passivation layer 163 is patterned using a patterned via layer 164 as an etching mask in the processes of manufacturing the display device 10, and thus, a separate mask for forming the passivation layer 163 is unnecessary. Accordingly, the number of masks for manufacturing the display device 10 may be reduced, such that economic efficiency of the processes of manufacturing the display device 10 may be secured.

The via layer 164 may have a substantially flat surface regardless of a shape or presence or absence of a pattern disposed thereunder. That is, the via layer 164 may serve to planarize an upper portion of the passivation layer 163. The via layer 164 may include an organic insulating material, for example, an organic material such as polyimide (PI).

A light emitting element layer may be disposed on the via layer 164. The light emitting element layer may include the first layer 200, the bank layer 400, the plurality of light emitting elements ED, and the second layer 700 described above with reference to FIG. 3. The light emitting element layer may further include a first insulating layer 510 and a second insulating layer 520.

The first layer 200 may be disposed on the via layer 164 in the display area DPA. The first layer 200 may be directly disposed on an upper surface of the via layer 164. The first layer 200 may not be disposed in the pad area PDA of the non-display area NDA.

The first electrode 210 may be in contact with and electrically connected to the source electrode SD2 of the transistor through the first electrode contact hole CTD penetrating through the via layer 164 and the passivation layer 163 and exposing the source electrode SD2 of the transistor. That is, the first electrode 210 may be electrically connected to the circuit element layer through the first electrode contact hole CTD.

The second electrode 220 may be in contact with and electrically connected to the first conductive pattern CDP1 through the second electrode contact hole CTS penetrating through the via layer 164 and the passivation layer 163 and exposing the first conductive pattern CDP1. The second electrode 220 may be electrically connected to the second voltage line VL2 through the first conductive pattern CDP1.

Meanwhile, it has been illustrated in FIG. 4 that the first and second electrode contact holes CTD and CTS overlap the first bank 430, but positions of the first and second electrode contact holes CTD and CTS are not limited thereto.

The first electrode 210 may be spaced apart from a first electrode 210 of another adjacent pixel PX with the separation part ROP interposed therebetween in the sub-area SA. Similarly, the second electrode 220 may be spaced apart from a second electrode 220 of another adjacent pixel PX with the separation part ROP interposed therebetween in the sub-area SA. Accordingly, the first electrode 210 and the second electrode 220 may expose the via layer 164 in the separation part ROP of the sub-area SA.

The first layer 200 may include a conductive material having high reflectivity. For example, the first layer 200 may include a metal such as silver (Ag), copper (Cu), aluminum (Al), molybdenum (Mo), or titanium (Ti), or include an alloy including aluminum (Al), nickel (Ni), lanthanum (La), or the like, as the material having the high reflectivity. However, the disclosure is not limited thereto, and the first layer 200 may further include a transparent conductive material. For example, the first layer 200 may include a material such as ITO, IZO, or ITZO. In some embodiments, the first layer 200 may have a structure in which one or more layers made of the transparent conductive material and one or more layers made of the metal having the high reflectivity are stacked or may be formed as one layer including the transparent conductive material and the metal having the high reflectivity. For example, the first layer 200 may have a stacked structure such as ITO/Ag/ITO, ITO/Ag/IZO, or ITO/Ag/ITZO/IZO.

The first insulating layer 510 may be disposed in the display area DPA and the pad area PDA of the non-display area NDA. The first insulating layer 510 may be disposed on the buffer layer 161 on which the first layer 200 is formed. The first insulating layer 510 may be disposed on the via layer 164 on which the first layer 200 is formed, in the display area DPA, and may be disposed on the buffer layer 161 in the pad area PDA.

The first insulating layer 510 may be disposed to cover the first electrode 210 and the second electrode 220 in the display area DPA. The first insulating layer 510 may serve to protect the first layer 200 and to insulate the first electrode 210 and the second electrode 220 from each other.

The first insulating layer 510 may define first and second contact parts CT1 and CT2 penetrating through the first insulating layer 510 and exposing at least portions of the first electrode 210 and the second electrode 220 in the sub-area SA of the display area DPA.

The first contact electrode 710 and the first electrode 210 may be electrically connected to each other through the first contact part CT1 penetrating through the first insulating layer 510, and the second contact electrode 720 and the second electrode 220 may be electrically connected to each other through the second contact part CT2 penetrating through the first insulating layer 510. Meanwhile, it has been illustrated in FIG. 4 that the first and second contact parts CT1 and CT2 exposing portions of the first layer 200 are positioned in the sub-area SA, but the disclosure is not limited thereto. For example, the first and second contact parts CT1 and CT2 exposing portions of the first layer 200 may also be positioned in the emission area EMA.

The first insulating layer 510 may not be disposed in the separation part ROP in the sub-area SA of the display area DPA. The first insulating layer 510 may expose the via layer 164 together with the first electrode 210 and the second electrode 220 in the sub-area SA of the display area DPA.

The first insulating layer 510 may be disposed on the buffer layer 161 in the pad area PDA. The first insulating layer 510 may be directly disposed on an upper surface of the buffer layer 161 in the pad area PDA.

The first insulating layer 510 may define the pad opening OP_PD exposing the first pad PE1 together with the buffer layer 161 and the second insulating layer 520 in the pad area PDA. Sidewalls of the buffer layer 161 and the first insulating layer 510 defining the pad opening OP_PD may be aligned with each other, but are not limited thereto. In the pad area PDA, inner sidewalls of the first insulating layer 510 may be disposed to overlap the first conductive layer 110, specifically, the first pad PE1.

The bank layer 400 may be disposed on the first insulating layer 510. The bank layer 400 may be disposed on the first insulating layer 510 and may be formed to have a height (e.g., a predetermined height). The bank layer 400 may include the first and second sub-banks 410 and 420 and the first bank 430. That is, the first and second sub-banks 410 and 420 and the first bank 430 may be formed of the bank layer 400.

Because the first bank 430 has a height and is disposed to surround the emission area EMA, the ink in which the plurality of light emitting elements ED are dispersed may be jetted into the emission area EMA, but may not be jetted into the sub-area SA, in the inkjet printing process for aligning the light emitting elements ED among the processes of manufacturing the display device 10.

The first and second sub-banks 410 and 420 may be disposed in the emission area EMA partitioned by the first bank 430. Heights of the first and second sub-banks 410 and 420 may be less than or equal to the height of the first bank 430.

The first sub-bank 410 and the second sub-bank 420 may serve to induce the plurality of light emitting elements ED to be disposed between the first electrode 210 and the second electrode 220 in the process for aligning the plurality of light emitting elements ED among the processes of manufacturing the display device 10. A space between the first sub-bank 410 and the second sub-bank 420 may provide an area in which the plurality of light emitting elements ED are disposed.

In addition, the first sub-bank 410 and the second sub-bank 420 may have inclined side surfaces to serve to change a traveling direction of light emitted from the light emitting elements ED and traveling toward the side surfaces of the first sub-bank 410 and the second sub-bank 420 into an upward direction. That is, the first and second sub-banks 410 and 420 may provide a space in which the light emitting elements ED are disposed and also serve as reflective partition walls changing the traveling direction of the light emitted from the light emitting elements ED into the upward direction.

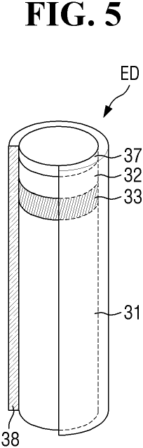

Meanwhile, it has been illustrated in FIG. 5 that each of side surfaces of a plurality of sub-banks 410 and 420 and the first bank 430 included in the bank layer 400 is inclined in a linear shape, but the disclosure is not limited thereto. For example, the side surfaces (or outer surfaces) of the plurality of sub-banks 410 and 420 and the side surfaces of the first bank 430 that are included in the bank layer 400 may also have a semicircular or semielliptical shape. In one or more embodiments, the bank layer 400 may include an organic insulating material such as polyimide (PI), but is not limited thereto.

The light emitting element ED may be disposed above the first insulating layer 510 in the emission area EMA. The light emitting element ED may be disposed in the emission area EMA, but may not be disposed in the sub-area SA. The light emitting element ED may be disposed between the first sub-bank 410 and the second sub-bank 420 in the emission area EMA. The light emitting element ED may be disposed so that both ends thereof contact the first electrode 210 and the second electrode 220, respectively.

The light emitting element ED may emit light of a corresponding wavelength band. For example, the light emitting element ED may emit light of a third color or blue light having a peak wavelength in the range of about 480 nm or less, for example, a peak wavelength in the range of about 445 nm to about 480 nm or less. The light emitting elements ED may be electrically connected to the first and second electrodes 210 and 220 and the conductive layers 110 and 130 of the circuit element layer through contact with the first and second contact electrodes 710 and 720, and may emit light of a corresponding wavelength band by electrical signals applied thereto.

The second insulating layer 520 may be disposed in the display area DPA and the pad area PDA of the non-display area NDA. The second insulating layer 520 may be disposed on the first insulating layer 510, above which the light emitting element ED is disposed, and on the bank layer 400.

The second insulating layer 520 may be disposed on the first insulating layer 510 above which the light emitting element ED is disposed and on the bank layer 400, in the display area DPA, but may expose both ends of the light emitting element ED. The second insulating layer 520 may be disposed on the first insulating layer 510 in the pad area PDA of the non-display area NDA.

The second insulating layer 520 may include a pattern part disposed on the light emitting element ED in the emission area EMA of the display area DPA. The pattern part may be disposed to partially surround an outer surface of the light emitting element ED, but may be disposed to expose both ends of the light emitting element ED. The pattern part may be disposed to extend in the second direction DR2 on the first insulating layer 510 and the light emitting element ED in plan view, thereby forming a linear or island-shaped pattern in each pixel PX. The pattern part of the second insulating layer 520 may protect the light emitting element ED, and fix the light emitting element ED in the processes of manufacturing the display device 10. In addition, the second insulating layer 520 may be disposed to fill a space between the light emitting element ED and the first insulating layer 510 disposed under the light emitting element ED in the emission area EMA of the display area DPA.

The second insulating layer 520 may define the first and second contact parts CT1 and CT2 penetrating through the second insulating layer 520 and exposing at least portions of the first electrode 210 and the second electrode 220 in the sub-area SA of the display area DPA. That is, the second insulating layer 520 may define the first contact part CT1 and the second contact part CT2 together with the first insulating layer 510 in the sub-area SA of the display area DPA.

In addition, the second insulating layer 520 may not be disposed in the separation part ROP in the sub-area SA of the display area DPA. The second insulating layer 520 may expose the via layer 164 together with the first electrode 210, the second electrode 220, and the first insulating layer 510 in the sub-area SA of the display area DPA.

The second insulating layer 520 may be disposed on the first insulating layer 510 in the pad area PDA. The second insulating layer 520 may be directly disposed on an upper surface of the first insulating layer 510 in the pad area PDA.

The second insulating layer 520 may define the pad opening OP_PD exposing the first pad PE1 together with the first insulating layer 510 and the buffer layer 161 in the pad area PDA. Sidewalls of the buffer layer 161, the first insulating layer 510, and the second insulating layer 520 defining the pad opening OP_PD may be aligned with each other, but are not limited thereto. In the pad area PDA, inner sidewalls of the second insulating layer 520 may be disposed to overlap the first conductive layer 110, specifically, the first pad PE1.

The second layer 700 may be disposed on the second insulating layer 520. The second layer 700 may be disposed in the display area DPA and the pad area PDA of the non-display area NDA. The second layer 700 may include the first contact electrode 710, the second contact electrode 720, and the pad electrode PE2. That is, the first contact electrode 710 and the second contact electrode 720 disposed in the display area DPA and the pad electrode PE2 of the wiring pad WPD disposed in the pad area PDA may be formed of the second layer 700.

The first contact electrode 710 may be disposed on the first electrode 210 in the emission area EMA. The first contact electrode 710 may be in contact with each of the first electrode 210 and one end of the light emitting element ED disposed on the first electrode 210.

The first contact electrode 710 may be in contact with the first electrode 210 exposed by the first contact part CT1 penetrating through the first insulating layer 510 and the second insulating layer 520 in the sub-area SA, and may be in contact with one end of the light emitting element ED in the emission area EMA. That is, the first contact electrode 710 may serve to electrically connect the first electrode 210 and one end of the light emitting element ED to each other.

The second contact electrode 720 may be disposed on the second electrode 220 in the emission area EMA. The second contact electrode 720 may be in contact with each of the second electrode 220 and the other end of the light emitting element ED disposed on the second electrode 220.

The second contact electrode 720 may be in contact with the second electrode 220 exposed by the second contact part CT2 penetrating through the first insulating layer 510 and the second insulating layer 520 in the sub-area SA, and may be in contact with the other end of the light emitting element ED in the emission area EMA. That is, the second contact electrode 720 may serve to electrically connect the second electrode 220 and the other end of the light emitting element ED to each other.

The first contact electrode 710 and the second contact electrode 720 may be spaced apart from each other on the light emitting element ED. For example, the first contact electrode 710 and the second contact electrode 720 may be spaced apart from each other with the second insulating layer 520 interposed therebetween. The first contact electrode 710 and the second contact electrode 720 may be electrically insulated from each other.

The pad electrode PE2 may be disposed in the pad area PDA of the non-display area NDA. The pad electrode PE2 may be disposed on the second insulating layer 520 in the pad area PDA. The pad electrode PE2 may be disposed to overlap the first pad PE1 in the pad area PDA. The pad electrode PE2 may be in contact with and electrically connected to the first pad PE1 through the pad opening OP_PD penetrating through the second insulating layer 520, the first insulating layer 510, and the buffer layer 161 and exposing the first pad PE1. The pad electrode PE2 may be used as a contact electrode of the wiring pad WPD in the pad area PDA.

The first contact electrode 710, the second contact electrode 720, and the pad electrode PE2 may be formed of the second layer 700, and may be thus formed on the same layer. In addition, the first contact electrode 710, the second contact electrode 720, and the pad electrode PE2 may include the same material, and may be thus formed of the same layer. That is, the first contact electrode 710, the second contact electrode 720, and the pad electrode PE2 may be substantially simultaneously formed through a single mask process. For example, the second layer 700 may include a conductive material. For example, the second layer 700 may include ITO, IZO, ITZO, aluminum (Al), or the like. As an example, the second layer 700 may include a transparent conductive material.

FIG. 5 is a schematic perspective view of a light emitting element according to one or more embodiments.

Referring to FIG. 5, the light emitting element ED is a particle type element, and may have a rod shape or a cylindrical shape having an aspect ratio (e.g., a predetermined aspect ratio). A length of the light emitting element ED may be greater than a diameter of the light emitting element ED, and the aspect ratio of the light emitting element ED may be about 6:5 to about 100:1, but the disclosure is not limited thereto.

The light emitting element ED may have a size of a nanometer scale (about 1 nm or more and less than about 1 µm) to a micrometer scale (about 1 µm or more and less than about 1 mm). In one or more embodiments, the light emitting element ED may have a size of a nanometer scale or may have a size of a micrometer scale, in both the length and the diameter. In some other embodiments, the diameter of the light emitting element ED may have a size of a nanometer scale, while the length of the light emitting element ED may have a size of a micrometer scale. In some embodiments, some of the light emitting elements ED have sizes of a nanometer scale in diameter and/or length, while the others of the light emitting elements ED may have a size of a micrometer scale in diameter and/or length.

In one or more embodiments, the light emitting element ED may be an inorganic light emitting diode. The inorganic light emitting diode may include a plurality of semiconductor layers. For example, the inorganic light emitting diode may include a first conductivity-type (e.g., n-type) semiconductor layer, a second conductivity-type (e.g., p-type) semiconductor layer, and an active semiconductor layer interposed between the first conductivity-type semiconductor layer and the second conductivity-type semiconductor layer. The active semiconductor layer may receive holes and electrons provided from the first conductivity-type semiconductor layer and the second conductivity-type semiconductor layer, respectively, and the holes and the electrons reaching the active semiconductor layer may be combined with each other to emit light.

In one or more embodiments, the above-described semiconductor layers may be sequentially stacked along one direction, which is a length direction of the light emitting element ED. The light emitting element ED may include a first semiconductor layer 31, an element active layer 33, and a second semiconductor layer 32 that are sequentially stacked in one direction. The first semiconductor layer 31, the element active layer 33, and the second semiconductor layer 32 may be the above-described first conductivity-type semiconductor layer, active semiconductor layer, and second conductivity-type semiconductor layer, respectively.

The first semiconductor layer 31 may be doped with a first conductivity-type dopant. The first conductivity-type dopant may be Si, Ge, Sn, or the like. In one or more embodiments, the first semiconductor layer 31 may be made of n-GaN doped with n-type Si.

The second semiconductor layer 32 may be disposed to be spaced apart from the first semiconductor layer 31 with the element active layer 33 interposed therebetween. The second semiconductor layer 32 may be doped with a second conductivity-type dopant such as Mg, Zn, Ca, Sr, or Ba. In one or more embodiments, the second semiconductor layer 32 may be made of p-GaN doped with p-type Mg.

The element active layer 33 may include a material having a single or multiple quantum well structure. As described above, the element active layer 33 may emit light by a combination of electron-hole pairs according to an electrical signal applied through the first semiconductor layer 31 and the second semiconductor layer 32.

In some embodiments, the element active layer 33 may have a structure in which semiconductor materials having large band gap energy and semiconductor materials having small band gap energy are alternately stacked, and may include other Group III to Group V semiconductor materials depending on a wavelength band of emitted light.

The light emitted from the element active layer 33 may be emitted not only to both end surfaces of the light emitting element ED in the length direction, but also to an outer circumferential surface (or an outer surface or a side surface) of the light emitting element. That is, an emission direction of the light from the element active layer 33 is not limited to one direction.

The light emitting element ED may further include an element electrode layer 37 disposed on the second semiconductor layer 32. The element electrode layer 37 may be in contact with the second semiconductor layer 32. The element electrode layer 37 may be an ohmic contact electrode, but is not limited thereto, and may also be a Schottky contact electrode.

The element electrode layer 37 may be disposed between the second semiconductor layer 32 and the electrode to serve to reduce resistance, when both ends of the light emitting element ED and the first and second contact electrodes 710 and 720 are electrically connected to each other, respectively, in order to apply an electrical signal to the first semiconductor layer 31 and the second semiconductor layer 32. The element electrode layer 37 may include at least one of aluminum (Al), titanium (Ti), indium (In), gold (Au), silver (Ag), indium tin oxide (ITO), indium zinc oxide (IZO), and indium tin zinc oxide (ITZO). The element electrode layer 37 may also include an n-type or p-type doped semiconductor material.

The light emitting element ED may further include an element insulating film 38 surrounding outer peripheral surfaces of the first semiconductor layer 31, the second semiconductor layer 32, the element active layer 33, and/or the element electrode layer 37. The element insulating film 38 may be disposed to surround at least an outer surface of the element active layer 33, and may extend in one direction in which the light emitting element ED extends. The element insulating film 38 may serve to protect the first semiconductor layer 31, the second semiconductor layer 32, the element active layer 33, and the element electrode layer 37. The element insulating film 38 may be made of materials having insulating properties to reduce or prevent the likelihood of an electrical short-circuit that may occur when the element active layer 33 is in direct contact with an electrode through which an electrical signal is transferred to the light emitting element ED. In addition, the element insulating film 38 protects the outer peripheral surfaces of the first and second semiconductor layers 31 and 32 as well as the element active layer 33, and may thus reduce or prevent a decrease in luminous efficiency.

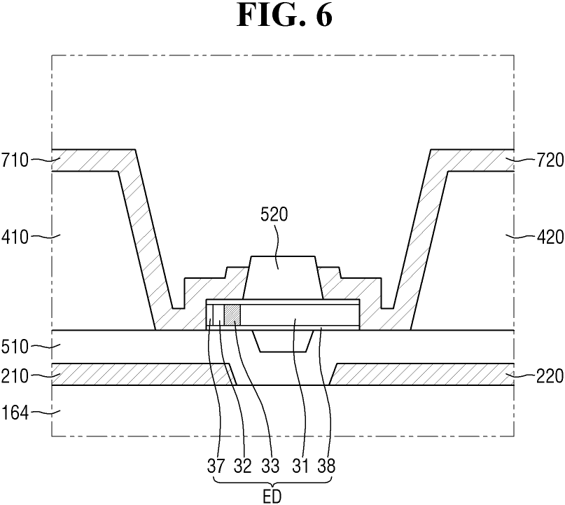

FIG. 6 is an enlarged cross-sectional view of the display device according to one or more embodiments.

An enlarged view of an area in which the light emitting element ED is disposed between the first electrode 210 and the second electrode 220 is illustrated in FIG. 6.

For example, the light emitting element ED may be disposed so that an extension direction of the light emitting element ED is parallel to one surface of the substrate SUB (or the via layer 164). The plurality of semiconductor layers included in the light emitting element ED may be sequentially disposed along a direction parallel to an upper surface of the via layer 164. For example, the first semiconductor layer 31, the element active layer 33, and the second semiconductor layer 32 of the light emitting element ED may be sequentially disposed parallel to the upper surface of the via layer 164.

For example, in the light emitting element ED, in a cross section crossing both ends of the light emitting element ED, the first semiconductor layer 31, the element active layer 33, the second semiconductor layer 32, and the element electrode layer 37 may be sequentially formed in a direction horizontal to the upper surface of the via layer 164.

The light emitting element ED may be disposed so that one end thereof is put on the first electrode 210 and the other end thereof is put on the second electrode 220. However, the disclosure is not limited thereto, and the light emitting element ED may also be disposed so that one end thereof is put on the second electrode 220 and the other end thereof is put on the first electrode 210.

The second insulating layer 520 may be disposed on the light emitting element ED. The second insulating layer 520 may be disposed to surround an outer surface of the light emitting element ED. In an area in which the light emitting element ED is disposed, the second insulating layer 520 may be disposed to surround the outer surface of the light emitting element ED, and in an area in which the light emitting element ED is not disposed, the second insulating layer 520 may be disposed on the first insulating layer 510 exposed by the light emitting element ED or the bank layer 400.

The first contact electrode 710 may be in contact with one end of the light emitting element ED exposed by the second insulating layer 520. For example, the first contact electrode 710 may be disposed to surround one end surface of the light emitting element ED exposed by the second insulating layer 520. The first contact electrode 710 may be in contact with the element insulating film 38 and the element electrode layer 37 of the light emitting element ED.

The second contact electrode 720 may be in contact with the other end of the light emitting element ED exposed by the second insulating layer 520. For example, the second contact electrode 720 may be disposed to surround the other end surface of the light emitting element ED exposed by the second insulating layer 520. The second contact electrode 720 may be in contact with the element insulating film 38 and the first semiconductor layer 31 of the light emitting element ED.

The first contact electrode 710 and the second contact electrode 720 may be spaced apart from each other with the second insulating layer 520 interposed therebetween. The first contact electrode 710 and the second contact electrode 720 may expose at least a portion of an upper surface of the second insulating layer 520.

The first contact electrode 710 and the second contact electrode 720 may be formed on the same layer and may include the same material. That is, the first contact electrode 710 and the second contact electrode 720 may be substantially simultaneously formed through a single mask process. Accordingly, an additional mask process for forming the first contact electrode 710 and the second contact electrode 720 is not required, and thus, efficiency of the processes of manufacturing the display device 10 may be improved.

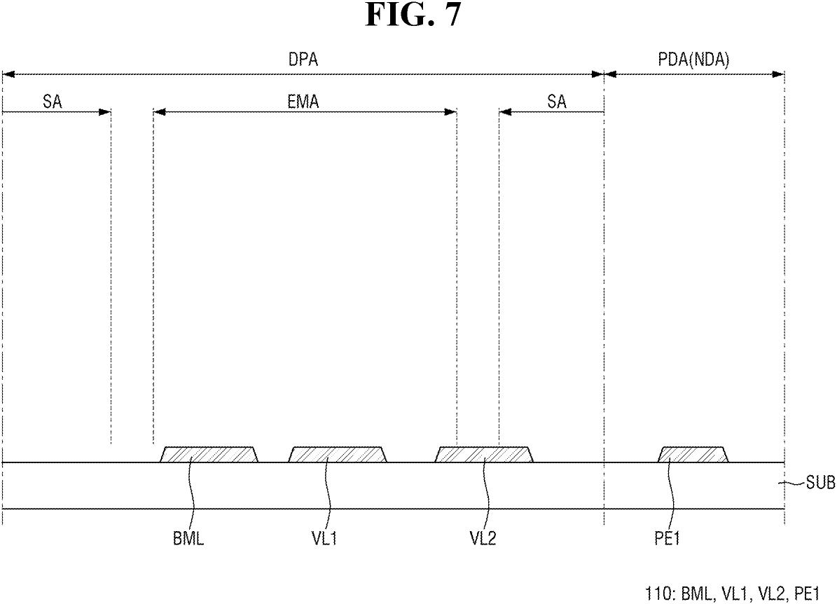

FIGS. 7 to 19 are cross-sectional views illustrating processes of manufacturing the display device of FIG. 4.

Referring to FIG. 7, first, a patterned first conductive layer 110 is formed on the substrate SUB. The patterned first conductive layer 110 may be formed by a mask process. For example, the patterned first conductive layer 110 as illustrated in FIG. 7 may be formed by entirely depositing a material layer for a first conductive layer on the substrate SUB and then patterning the material layer for a first conductive layer through a photolithography process. As described above, the first conductive layer 110 may include the first voltage line VL1, the second voltage line VL2, the light blocking pattern BML, and the first pad PE1 disposed in the pad area PDA of the non-display area NDA.

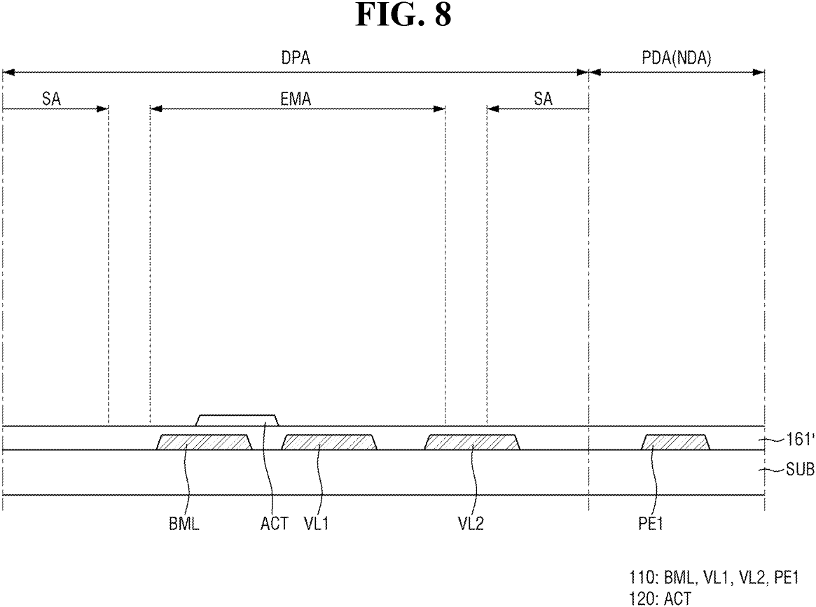

Next, referring to FIG. 8, a buffer layer 161' is entirely formed on the substrate SUB on which the first conductive layer 110 is formed. The buffer layer 161' may completely cover the first conductive layer 110. For example, the buffer layer 161' may completely cover the first voltage line VL1, the second voltage line VL2, and the light blocking pattern BML disposed in the display area DPA and the first pad PE1 disposed the pad area PDA of the non-display area NDA.

Next, the semiconductor layer 120 is formed on the buffer layer 161'. The semiconductor layer 120 may be formed by a mask process. For example, the semiconductor layer 120 as illustrated in FIG. 8 may be formed by entirely depositing a semiconductor on the buffer layer 161' and then patterning the semiconductor through a photolithography process.

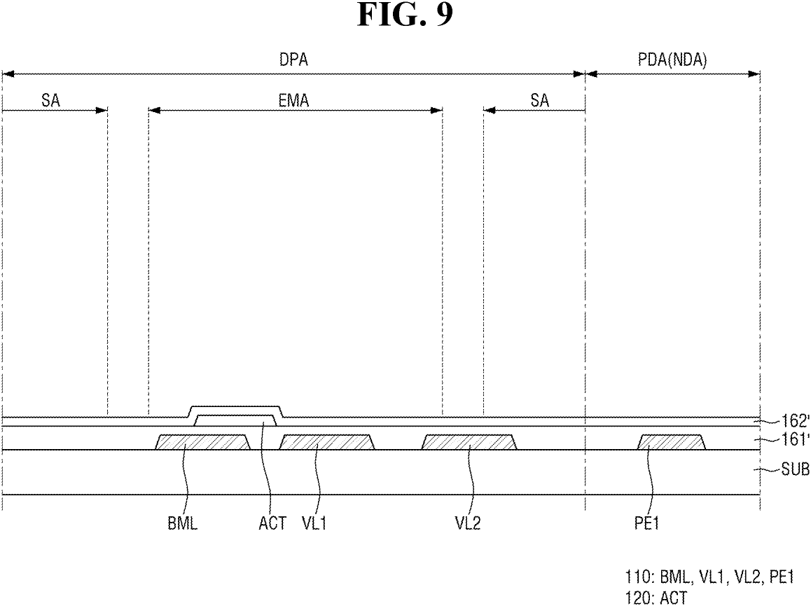

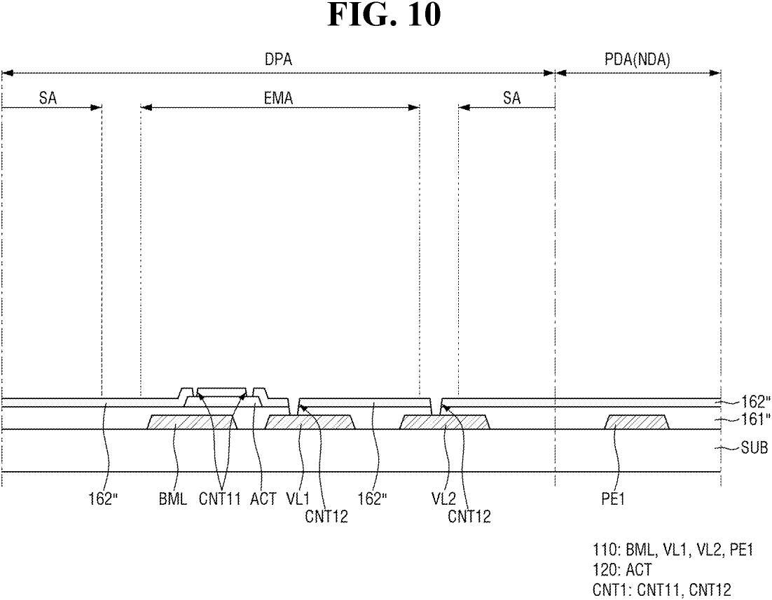

Next, referring to FIGS. 9 and 10, a material layer 162' for a gate insulating film is formed on the buffer layer 161' on which the semiconductor layer 120 is formed, and a plurality of first contact holes CNT1 exposing the first conductive layer 110 or the semiconductor layer 120 are formed. The plurality of first contact holes CNT1 may be formed by a mask process.

For example, as illustrated in FIG. 9, the material layer 162' for a gate insulating film is entirely formed on the buffer layer 161' on which the semiconductor layer 120 is formed. The material layer 162' for a gate insulating film may completely cover the semiconductor layer 120.

Next, as illustrated in FIG. 10, first contact holes CNT11 exposing portions of the semiconductor layer 120 and first contact holes CNT12 exposing portions of the first conductive layer 110 are formed. The first contact holes CNT11 exposing portions of the semiconductor layer 120 may penetrate through a material layer 162" for a gate insulating film, and the first contact holes CNT12 exposing portions of the first conductive layer 110 may penetrate through the material layer 162" for a gate insulating film and a buffer layer 161". As described above, the first contact holes CNT11 and CNT12 may be formed by a mask process.

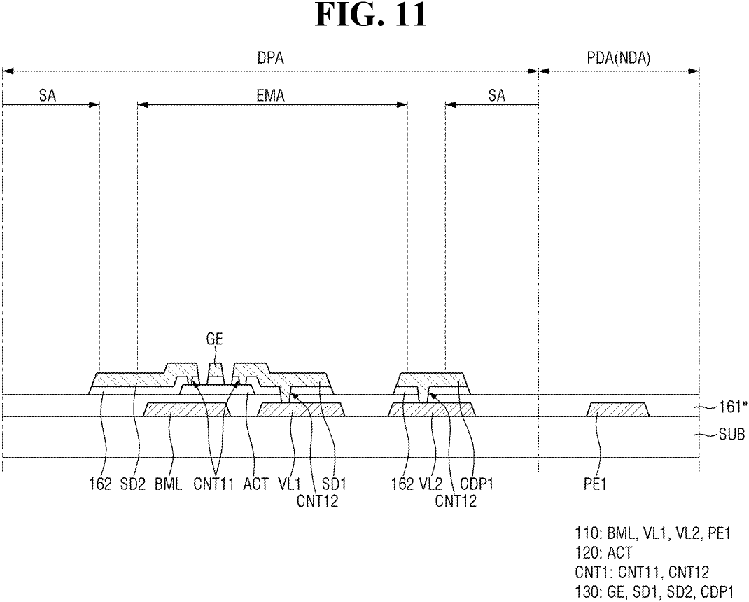

Next, referring to FIG. 11, a patterned gate insulating film 162 and a patterned second conductive layer 130 are formed on the buffer layer 161" in which the first contact holes CNT1 are formed. The patterned gate insulating film 162 and the patterned second conductive layer 130 may be formed by a single mask process. Through this process, sidewalls of the second conductive layer 130 and sidewalls of the gate insulating film 162 may be aligned with each other. As described above, the second conductive layer 130 may include the gate electrode GE, the drain electrode SD1, the source electrode SD2, and the first conductive pattern CDP1. In one or more embodiments, the second conductive layer 130 may not be formed in the pad area PDA of the non-display area NDA.

For example, a material layer for a second conductive layer is entirely deposited on the material layer 162' for a gate insulating film in which the first contact holes CNT1 are formed. Next, a photoresist layer is applied onto the material layer for a second conductive layer, a photoresist pattern is formed in the photoresist layer through exposure and development, and the material layer for a second conductive layer and the material layer 162" for a gate insulating film, in which the first contact holes CNT1 are formed, are then sequentially etched using the photoresist pattern as an etching mask. Thereafter, the photoresist pattern is removed.

A case where the photoresist pattern is used as the etching mask until the gate insulating film 162 is patterned has been described by way of example hereinabove, but a patterned upper layer (e.g., the patterned second conductive layer 130) may also be used as a hard mask for etching a lower layer (e.g., the gate insulating film 162). In this case, the photoresist pattern may be used as an etching mask together with the hard mask. As another example, after a hard mask is formed, the photoresist pattern is removed, and a lower layer may be etched using the hard mask as an etching mask.

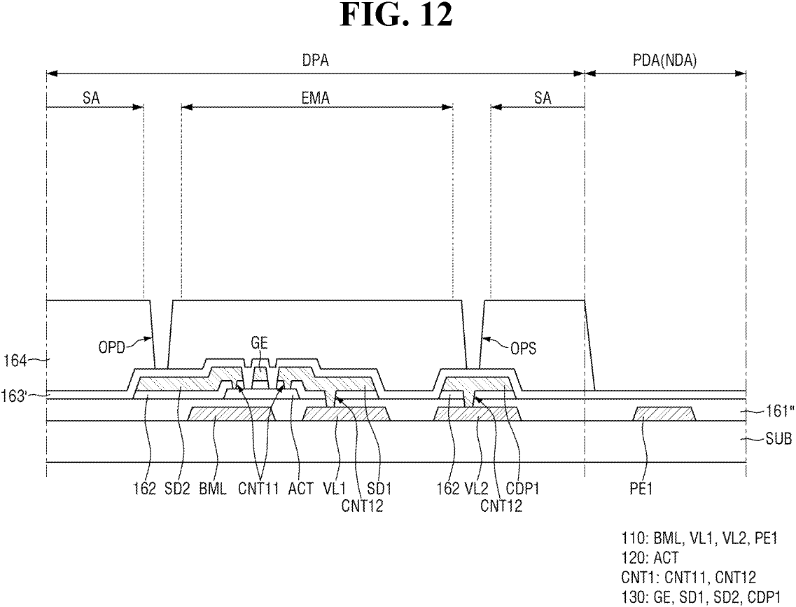

Next, referring to FIG. 12, a material layer 163' for a passivation layer is stacked on the buffer layer 161" on which the second conductive layer 130 is formed, and a patterned via layer 164 is formed.

The material layer 163' for a passivation layer may be entirely disposed over the display area DPA and the non-display area NDA, and may completely cover the patterned second conductive layer 130. The patterned via layer 164 may be disposed in the display area DPA, but may not be disposed in the pad area PDA of the non-display area NDA. Accordingly, the patterned via layer 164 may expose the material layer 163' for a passivation layer formed in the pad area PDA of the non-display area NDA.

The patterned via layer 164 may be disposed in the display area DPA, and may include a first opening OPD overlapping the source electrode SD2 and a second opening OPS overlapping the first conductive pattern CDP1. The first opening OPD may expose a portion of the material layer 163' for a passivation layer overlapping the source electrode SD2, and the second opening OPS may expose a portion of the material layer 163' for a passivation layer overlapping the first conductive pattern CDP1. The first opening OPD may correspond to the first electrode contact hole CTD, and the second opening OPS may correspond to the second electrode contact hole CTS.

The patterned via layer 164 may be formed by a mask process. For example, the material layer 163' for a passivation layer is entirely deposited on the buffer layer 161" on which the second conductive layer 130 is formed. Next, the patterned via layer 164 may be formed by applying an organic material layer for a via layer onto the material layer 163' for a passivation layer, removing the organic material layer for a via layer disposed in the pad area PDA of the non-display area NDA through exposure and development, and then forming the first and second openings OPD and OPS.

Meanwhile, when the organic material layer for a via layer is applied, the buffer layer 161" is disposed to cover the first pad PE1 in the pad area PDA, and may thus prevent the organic material layer for a via layer from being in direct contact with the first pad PE1.

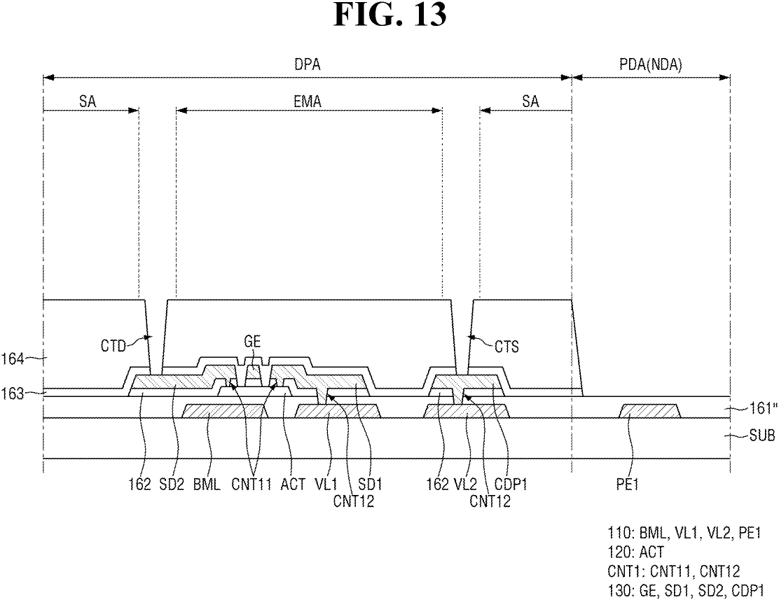

Next, referring to FIG. 13, the material layer 163' for a passivation layer is etched using the patterned via layer 164 as an etching mask to form a patterned passivation layer 163. A process of forming the patterned passivation layer 163 may not require a separate mask process.

For example, when the material layer 163' for a passivation layer disposed under the patterned via layer 164 is etched using the patterned via layer 164 of FIG. 12 as the etching mask, the material layer 163' for a passivation layer exposed by the patterned via layer 164 may be etched. Accordingly, the material layer 163' for a passivation layer formed in the pad area PDA of the non-display area NDA and the material layer 163' for a passivation layer overlapping the first and second openings OPD and OPS in the display area DPA are etched, such that the patterned passivation layer 163 may have the same pattern as the patterned via layer 164, as illustrated in FIG. 13. In addition, sidewalls of the passivation layer 163 may be aligned with sidewalls of the via layer 164, but are not limited thereto.

Through the process, the first electrode contact hole CTD penetrating through the via layer 164 and the passivation layer 163 and exposing the source electrode SD2 and the second electrode contact hole CTS penetrating through the via layer 164 and the passivation layer 163 and exposing the first conductive pattern CDP1 may be formed.

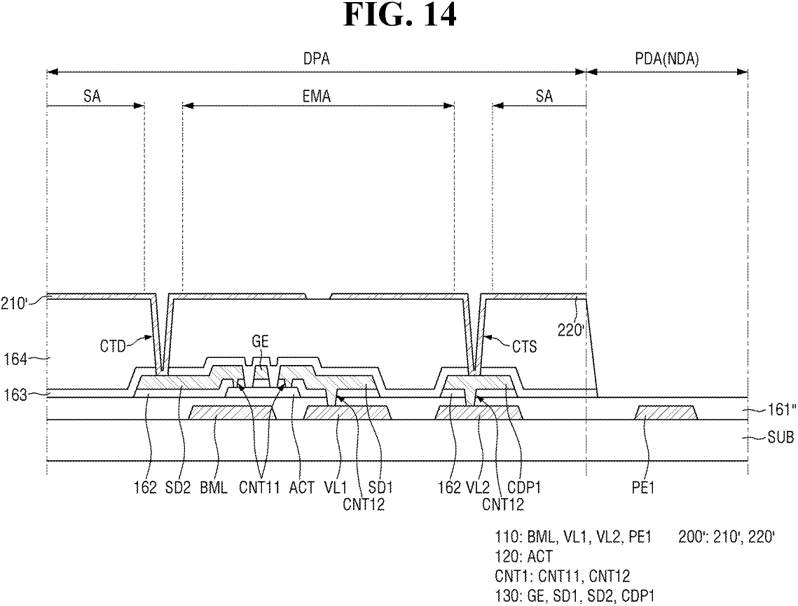

Next, referring to FIG. 14, a patterned alignment line layer 200' is formed on the via layer 164 in which the first and second electrode contact holes CTD and CTS are formed. The patterned alignment line layer 200' may be formed by a mask process.

The alignment line layer 200' may be a layer corresponding to the first layer 200 of the display device 10. The patterned alignment line layer 200' may include a first alignment line 210' and a second alignment line 220' spaced apart from each other. The first alignment line 210' may correspond to the first electrode 210, and the second alignment line 220' may correspond to the second electrode 220. The first alignment line 210' corresponds to the first electrode 210, and the second alignment line 220' corresponds to the second electrode 220, but the first alignment line 210' and the second alignment line 220' may extend in the second direction DR2 to be connected to alignment lines of a neighboring pixel PX rather than being separated from the alignment lines of the neighboring pixel PX in the sub-area SA.

The patterned alignment line layer 200' as illustrated in FIG. 14 may be formed by entirely depositing a material layer for a first layer on the buffer layer 161" on which the patterned via layer 164 is formed and then patterning the material layer for a first layer through a photolithography process.

Meanwhile, the material layer for a first layer may be deposited on the via layer 164 in the display area DPA. The material layer for a first layer may also be deposited on inner portions of the first electrode contact hole CTD and the second electrode contact hole CTS in the display area DPA to be in contact with and electrically connected to respective portions of the second conductive layer 130.

In addition, the material layer for a first layer may be deposited on the buffer layer 161" in the pad area PDA of the non-display area NDA. Even though the material layer for a first layer is deposited to overlap the first pad PE1 in the pad area PDA, the buffer layer 161" is formed to completely cover the first pad PE1 in the pad area PDA, and may thus prevent the first pad PE1 from being damaged by an etchant used in a process of etching the material layer for a first layer.

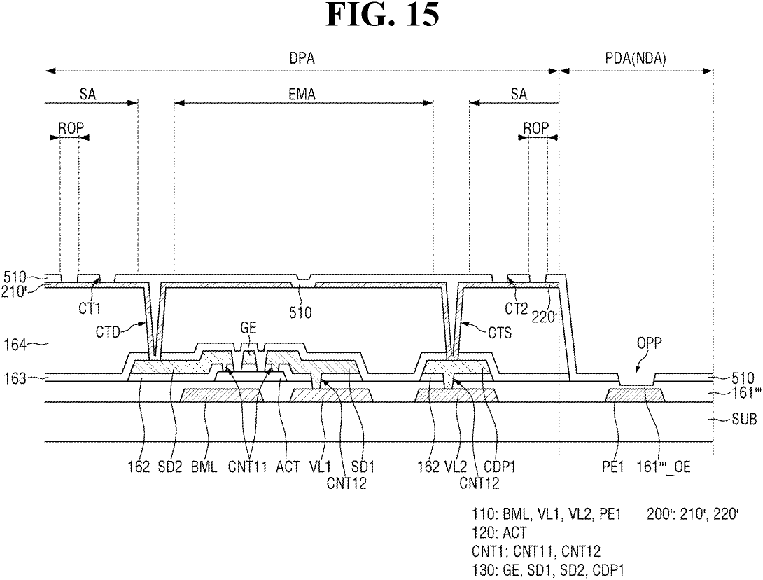

Next, referring to FIG. 15, a patterned first insulating layer 510 is formed. The patterned first insulating layer 510 may be formed by a mask process.

For example, a material layer for a first insulating layer is entirely deposited on the via layer 164, on which the patterned alignment line layer 200' is formed, and the buffer layer 161". The material layer for a first insulating layer may be deposited on the via layer 164 on which the alignment line layer 200' is formed, in the display area DPA, and may be disposed on a buffer layer 161"' in the pad area PDA of the non-display area NDA.

Next, a photoresist pattern exposing portions of the alignment line layer 200' in the display area DPA and exposing a portion of the first pad PE1 in the pad area PDA of the non-display area NDA may be formed on the material layer for a first insulating layer, and the material layer for a first insulating layer may be etched using the photoresist pattern as an etching mask to form the patterned first insulating layer 510 as illustrated in FIG. 15.

The patterned first insulating layer 510 may include a separation part ROP, a first contact part CT1, and a second contact part CT2 that are disposed in the sub-area SA and expose portions of the alignment line layer 200', in the display area DPA. In addition, the patterned first insulating layer 510 may include a first pad opening OPP overlapping the first pad PE1 in the pad area PDA.

Meanwhile, in the process of forming the patterned first insulating layer 510, a partial region 161"'_OE of the buffer layer 161'" disposed in the pad area PDA and overlapping the first pad opening OPP may be overetched as illustrated in FIG. 15. Accordingly, a thickness of the partial region 161"'_OE of the buffer layer 161'" overlapping the first pad opening OPP may be reduced.

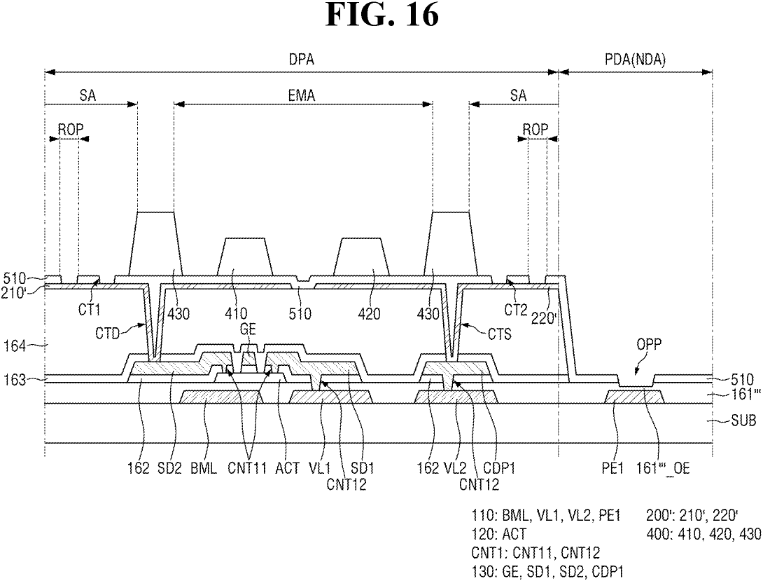

Next, referring to FIG. 16, a patterned bank layer 400 is formed on the first insulating layer 510. The patterned bank layer 400 may be formed by a mask process. For example, the patterned bank layer 400 as illustrated in FIG. 16 may be formed by applying an organic material layer for a bank layer onto the buffer layer 161"' on which the first insulating layer 510 is formed and then performing exposure and development on the organic material layer for a bank layer. The bank layer 400 having a different height for each region may be formed using a halftone mask, a slit mask, or the like.

Meanwhile, the first insulating layer 510 is formed to cover the alignment line layer 200' before the bank layer 400 is formed, and may thus prevent the alignment line layer 200' from being damaged by the organic material layer for a bank layer in a process of forming the bank layer 400. In addition, the buffer layer 161"'_OE remains on the first pad PE1 in the pad area PDA, and may thus prevent the first pad PE1 from being damaged by the organic material layer for a bank layer.

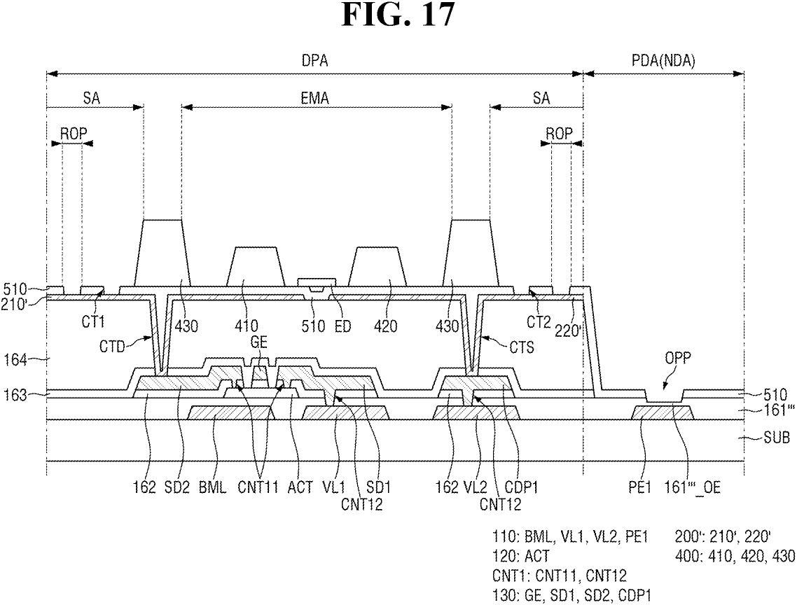

Next, referring to FIG. 17, the light emitting element ED is disposed in the emission area EMA of the display area DPA. The plurality of light emitting elements ED may be disposed on the first insulating layer 510 under which the alignment line layer 200' is formed, through an inkjet printing process. When alignment signals are applied to the first and second alignment lines 210' and 220' after ink, in which the light emitting elements ED are dispersed, is jetted into the emission area EMA partitioned by the first bank 430 of the bank layer 400, the light emitting elements ED in the ink may be seated on the first insulating layer 510 between the first alignment line 210' and the second alignment line 220' while positions and orientation directions thereof are changed.

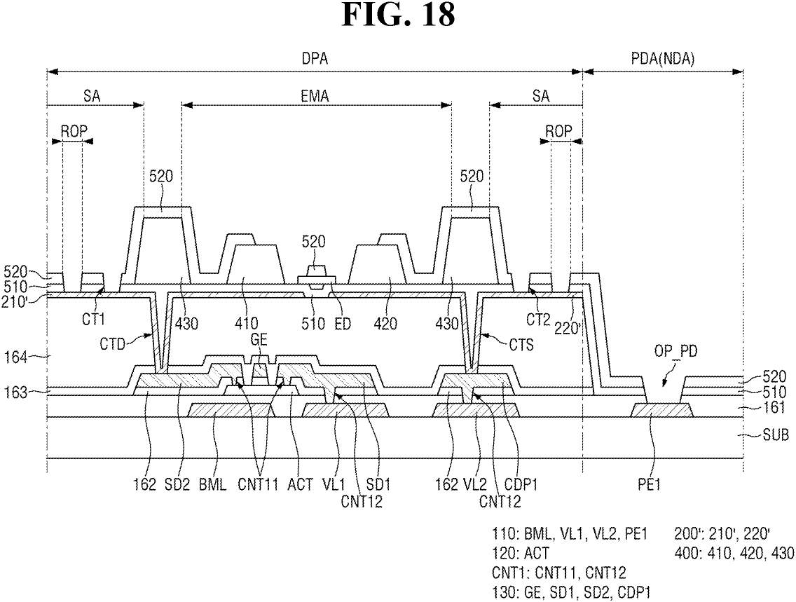

Next, referring to FIG. 18, a patterned second insulating layer 520 is formed on the first insulating layer 510 on which the light emitting element ED and the bank layer 400 are disposed. The patterned second insulating layer 520 may be formed by a mask process.

For example, a material layer for a second insulating layer is entirely deposited on the first insulating layer 510 on which the light emitting element ED and the bank layer 400 are formed. Next, a photoresist pattern exposing portions of the alignment line layer 200' in the display area DPA and exposing a portion of the first pad PE1 in the pad area PDA of the non-display area NDA may be formed on the material layer for a second insulating layer, and the material layer for a second insulating layer may be etched using the photoresist pattern as an etching mask to form the patterned second insulating layer 520 as illustrated in FIG. 18.

The patterned second insulating layer 520 may include a separation part ROP, a first contact part CT1, and a second contact part CT2 that are disposed in the sub-area SA and expose portions of the alignment line layer 200', in the display area DPA. The patterned second insulating layer 520 may include a pattern part exposing both ends of the light emitting element ED disposed in the emission area EMA in the display area DPA. The pattern part may be disposed on the light emitting element ED and may expose both ends of the light emitting element ED.

In addition, the patterned second insulating layer 520 may define the pad opening OP_PD overlapping the first pad PE1 in the pad area PDA. Meanwhile, in the process of forming the patterned second insulating layer 520, the partial region 161"'E (see FIG. 17) of the buffer layer 161'" disposed in the pad area PDA and overlapping the pad opening OP_PD may be overetched to expose an upper surface of the first pad PE1. Therefore, the pad opening OP_PD penetrating through the second insulating layer 520, the first insulating layer 510, and the buffer layer 161 and exposing the first pad PE1 may be formed in the pad area PDA.

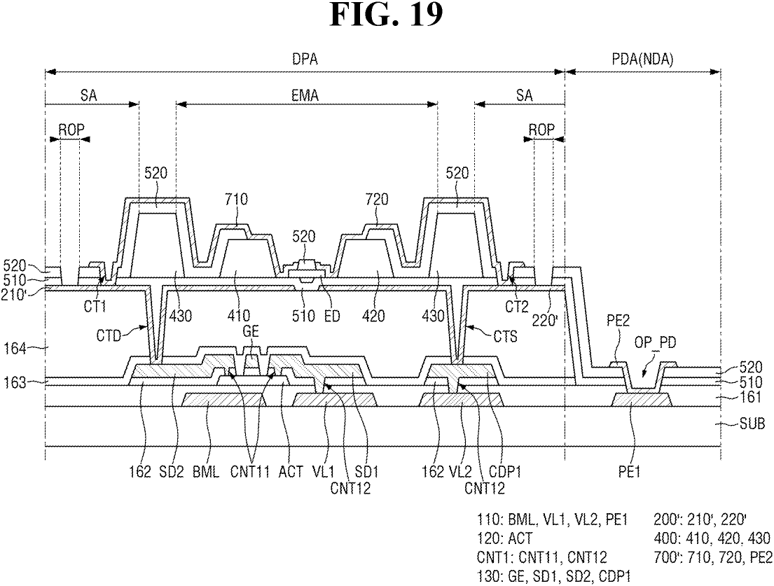

Next, referring to FIG. 19, a patterned second layer 700 is formed on the second insulating layer 520. The patterned second layer 700 may be formed by a mask process. For example, the patterned second layer 700 as illustrated in FIG. 19 may be formed by entirely depositing a material layer for a second layer on the second insulating layer 520 and then patterning the material layer for a second layer through a photolithography process. As described above, the second layer 700 may include the first contact electrode 710, the second contact electrode 720, and the pad electrode PE2.

Through the process, the first contact electrode 710 may also be deposited on an inner portion of the first contact part CT1 to be in contact with and electrically connected to a portion of the first alignment line 210', and the second contact electrode 720 may also be deposited on an inner portion of the second contact part CT2 to be in contact with and electrically connected to a portion of the second alignment line 220'. In addition, the pad electrode PE2 may also be deposited on an inner portion of the pad opening OP_PD to be in contact with and electrically connected to the first pad PE1 of the first conductive layer 110.

Next, referring to FIGS. 19 and 4, the first electrode 210 and the second electrode 220 separated in the separation part ROP as illustrated in FIG. 4 are formed by cutting the alignment line layer 200' overlapping the separation part ROP. Through the cutting process, the alignment line layer 200' overlapping the separation part ROP may be removed to expose one surface of the via layer 164.

With the processes of manufacturing the display device 10 according to one or more embodiments, the number of masks may be reduced by forming the plurality of wirings using the first conductive layer 110 and the second conductive layer 130 and electrically connecting the semiconductor layer 120 and the first conductive layer 110 to each other through the second conductive layer 130. In addition, the passivation layer 163 is patterned using the patterned via layer 164 as the etching mask, and thus, a separate mask for forming the passivation layer 163 is unnecessary, such that economic efficiency of the processes of manufacturing the display device 10 may be secured.

In addition, the wiring pad WPD and the pad electrode PE2 having excellent reliability may be formed by forming the first pad PE1 using the first conductive layer 110. For example, a process of patterning the first insulating layer 510 or the second insulating layer 520 is performed in a state in which the first conductive layer 110 disposed in the pad area PDA is covered by the buffer layer 161 before the process of patterning the first insulating layer 510 or the second insulating layer 520, and thus, direct contact between the first pad PE1 and a chemical material (e.g., an etchant or a material layer) used in the process of patterning the first insulating layer 510 or the second insulating layer 520 may be reduced or prevented to reduce or prevent the likelihood of the first pad PE1 being damaged.

In addition, a structure in which the second layer 700 and the first conductive layer 110 may be in direct contact with and electrically connected to each other may be implemented without disposing an additional connection pattern between the second layer 700 and the first conductive layer 110. Accordingly, the display device 10 may be manufactured without additionally designing a connection pattern connecting the second layer 700 and the first conductive layer 110 to each other, and thus, a design space of the display device 10 is additionally secured, such that a design of the display device 10 may be easy.

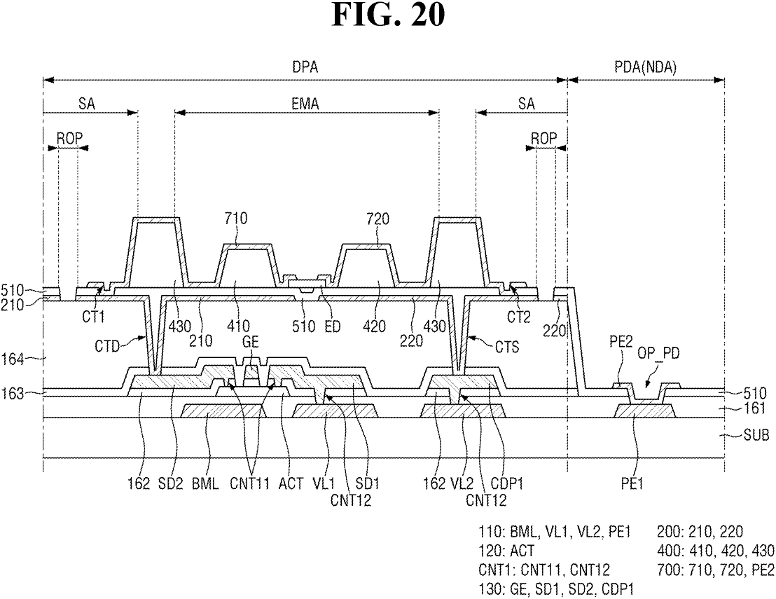

FIG. 20 is a cross-sectional view of a display device according to one or more other embodiments.

Referring to FIG. 20, a display device 10 according to one or more embodiments is different from the display device 10 of FIG. 4 in that the second insulating layer 520 is omitted. For example, when the second insulating layer 520 is omitted, sidewalls of the first insulating layer 510 may define the first contact part CT1 and the second contact part CT2. In addition, sidewalls of the buffer layer 161 and the first insulating layer 510 may define the pad opening OP_PD disposed in the pad area PDA.

In one or more embodiments, even though the second insulating layer 520 is omitted, the pad opening OP_PD defined by the sidewalls of the buffer layer 161 and the sidewalls of the first insulating layer 510 may be formed by overetching the buffer layer 161 overlapping the pad opening OP_PD in a process of patterning the first insulating layer 510 to expose the first pad PE1.

In one or more embodiments, the second insulating layer 520 is omitted, and thus, a mask process of patterning the second insulating layer 520 among the processes of manufacturing the display device 10 is omitted, such that economic efficiency of the processes of manufacturing the display device 10 may be secured.

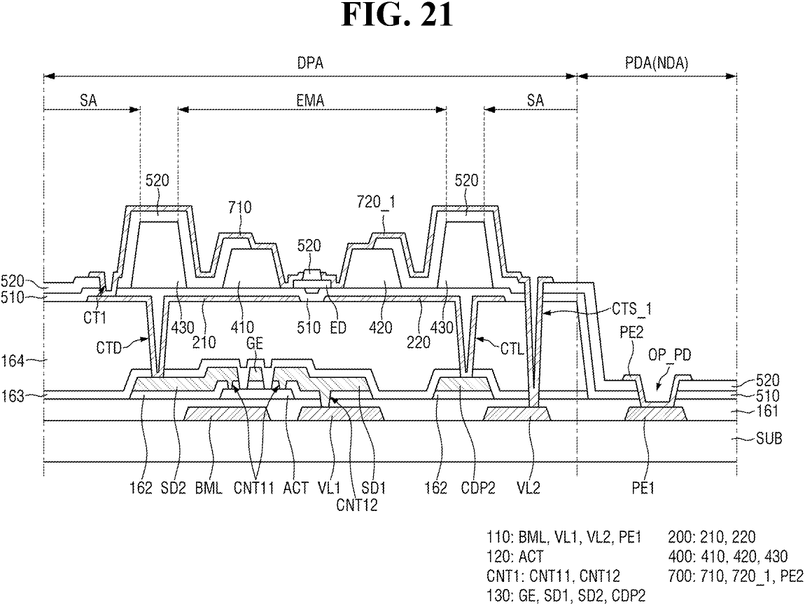

FIG. 21 is a cross-sectional view of a display device according to still one or more other embodiments.

Referring to FIG. 21, a display device 10 according to one or more embodiments is different from the display device according to one or more embodiments of FIG. 4 in that the second electrode 220 is in contact with and electrically connected to a second conductive pattern CDP2 through a third electrode contact hole CTL, and a second contact electrode 720_1 is in contact with and electrically connected to the second voltage line VL2 through a second electrode contact hole CTS_1.

For example, the second electrode 220 may be electrically connected to the second conductive pattern CDP2 through the third electrode contact hole CTL penetrating through the via layer 164 and the passivation layer 163. The second conductive pattern CDP2 may be a connection pattern applying an alignment signal to an alignment line in an alignment process for aligning the light emitting elements ED among processes of manufacturing the display device 10.

In one or more embodiments, in the display area DPA, a partial region of the second layer 700 may be in contact with and electrically connected to a partial region of the first conductive layer 110 through a hole penetrating through the first insulating layer 510, the via layer 164, the passivation layer 163, and the buffer layer 161 and exposing the partial region of the first conductive layer 110. For example, the second contact electrode 720_1 may be in contact with and electrically connected to the second voltage line VL2 through the second electrode contact hole CTS_1 penetrating through the second insulating layer 520, the first insulating layer 510, the via layer 164, the passivation layer 163, and the buffer layer 161 and exposing the second voltage line VL2 of the first conductive layer 110.

A process of forming the second electrode contact hole CTS_1 connecting the second contact electrode 720_1 and the second voltage line VL2 of the first conductive layer 110 to each other may include forming the buffer layer 161 so as to cover the second voltage line VL2, and forming a patterned via layer 164 overlapping the second voltage line VL2 covered by the buffer layer 161 but exposing the buffer layer 161. Next, the buffer layer 161 overlapping the second voltage line VL2 may be exposed through a process of patterning the passivation layer 163 using the patterned via layer 164. Next, a portion of the buffer layer 161 exposed by the via layer 164 and the passivation layer 163 may be overetched in a process of patterning the first insulating layer 510. Next, the buffer layer 161 remaining in the process of patterning the first insulating layer 510 may be overetched in a process of patterning the second insulating layer 520 to form the second electrode contact hole CTS_1 penetrating through the second insulating layer 520, the first insulating layer 510, the via layer 164, the passivation layer 163, and the buffer layer 161 and exposing the second voltage line VL2 of the first conductive layer 110.

Accordingly, also in the display area DPA, similar to the pad area PDA, the second layer 700 and the first conductive layer 110 may be in contact with and electrically connected to each other. Meanwhile, a connection relationship between the first conductive layer 110 and the second layer 700 illustrated in FIG. 21 may be only an example. As another example, another pattern of the first conductive layer 110 and the first contact electrode 710 of the second layer 700 may also be directly connected to each other.

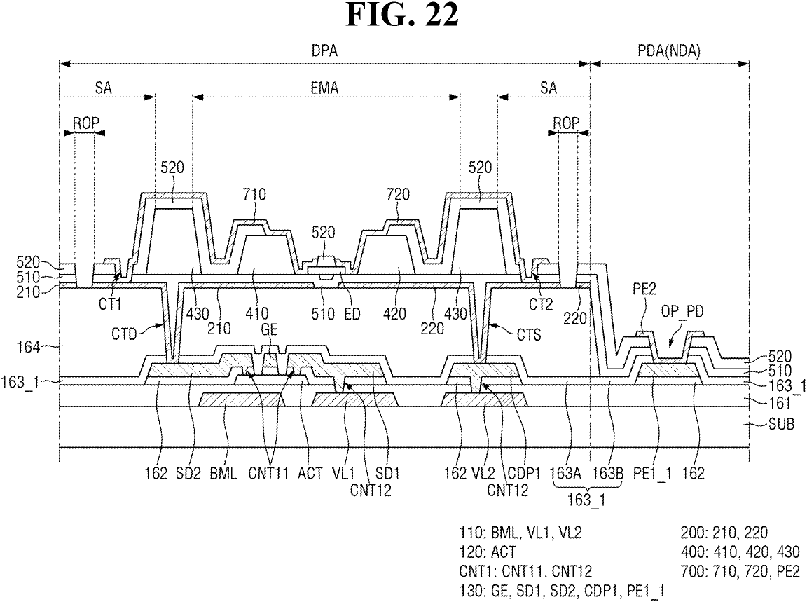

FIG. 22 is a cross-sectional view of a display device according to still one or more other embodiments.

Referring to FIG. 22, a display device 10 according to one or more embodiments is different from the display device 10 of FIG. 4 in that a passivation layer 163_1 is also disposed in the pad area PDA of the non-display area NDA and a first pad PE1_1 is formed of the second conductive layer 30.

For example, the first conductive layer 110 may include the light blocking pattern BML, the first voltage line VL1, and the second voltage line VL2 disposed in the display area DPA. In one or more embodiments, the first conductive layer 110 may not be disposed in the pad area PDA of the non-display area NDA.

The buffer layer 161 may be disposed on the first conductive layer 110. In the pad area PDA, the buffer layer 161 may not include a hole penetrating through the buffer layer 161. That is, the buffer layer 161 may entirely cover the substrate SUB in the pad area PDA.

The semiconductor layer 120 may be disposed on the buffer layer 161, and the gate insulating film 162 including a plurality of first contact holes CNT1 may be disposed on the buffer layer 161 in which the semiconductor layer 120 is formed. The second conductive layer 130 may be disposed on the gate insulating film 162.

In one or more embodiments, the second conductive layer 130 may include the drain electrode SD1, the source electrode SD2, the gate electrode GE, and the first pad PE1_1. That is, the drain electrode SD1, the source electrode SD2, the gate electrode GE, and the first conductive pattern CDP1 disposed in the display area DPA and the first pad PE1_1 disposed in the pad area PDA of the non-display area NDA may be formed of the second conductive layer 130.

The first pad PE1_1 may be one of the wiring pads WPD of the plurality of wirings described above. For example, the first pad PE1_1 may be one of the first voltage pad WPD_VL1, the second voltage pad WPD_VL2, the data pad WPD_DT, or the initialization voltage pad WPD_Vint. For example, when the first pad PE1_1 is the wiring pad WPD of the scan lines SL1 and SL2, the first pad PE1_1 may be the scan pad WPD_SC.

The gate insulating film 162 disposed between the first pad PE1_1 and the buffer layer 161 may have the same pattern as the first pad PE1_1 as described above. Sidewalls of the first pad PE1_1 may be aligned with sidewalls of the gate insulating film 162 disposed under the first pad PE1_1, but are not limited thereto.

In one or more embodiments, the passivation layer 163_1 may be disposed on the second conductive layer 130 in the display area DPA and the non-display area NDA. The passivation layer 163_1 may include a first area 163A disposed in the display area DPA and a second area 163B disposed in the non-display area NDA.

The first area 163A of the passivation layer 163_1 may be disposed to cover the second conductive layer 130 in the display area NDA. The first area 163A of the passivation layer 163_1 may define a first electrode contact hole CTD and a second electrode contact hole CTS together with the via layer 164.

The second area 163B of the passivation layer 163_1 may not be formed in a portion of the pad area PDA of the non-display area NDA. The second area 163B of the passivation layer 163_1 may expose at least a portion of the first pad PE1_1. For example, the second area 163B of the passivation layer 163_1 may cover the sidewalls of the first pad PE1_1 and the gate insulating film 162 disposed in the pad area PDA, but may expose a portion of an upper surface of the first pad PE1_1. The second area 163B of the passivation layer 163_1 may define a pad opening OP_PD exposing the first pad PE1_1 together with the first insulating layer 510 and the second insulating layer 520.

Sidewalls of the first insulating layer 510, the second insulating layer 520 and the passivation layer 163_1 (specifically, the second area 163B of the passivation layer 163_1) defining the pad opening OP_PD in the pad area PDA may be aligned with each other.

With the display device 10 according to one or more embodiments, the first pad PE1_1 may be formed using the second conductive layer 130, and the pad electrode PE2 of the second layer 700 and the first pad PE1_1 of the second conductive layer 130 may be brought into contact with and electrically connected to each other through the pad opening OP_PD defined by the sidewalls of the first insulating layer 510, the second insulating layer 520, and the passivation layer 163_1.

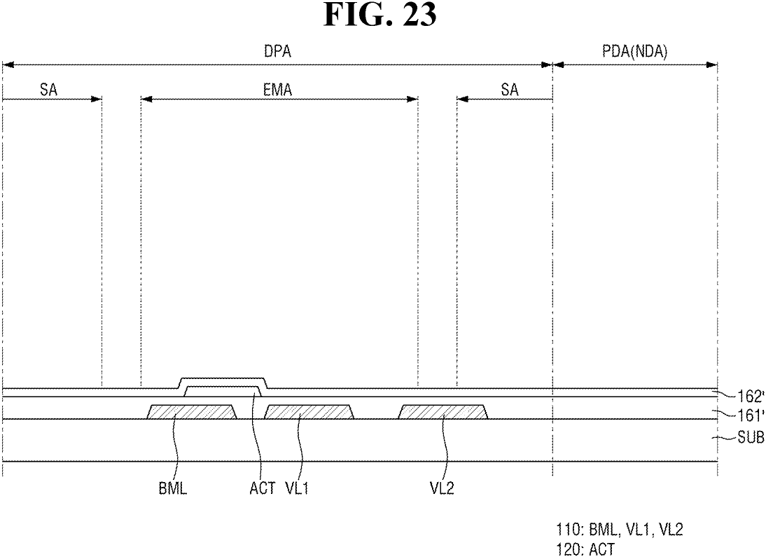

FIGS. 23 to 32 are cross-sectional views illustrating processes of manufacturing the display device of FIG. 22.

First, referring to FIG. 23, a patterned first conductive layer 110 is formed on the substrate SUB, and a buffer layer 161' is entirely formed on the substrate SUB on which the first conductive layer 110 is formed. Next, a semiconductor layer 120 is formed on the buffer layer 161', and a material layer 162' for a gate insulating film is formed on the buffer layer 161' on which the semiconductor layer 120 is formed.

In one or more embodiments, the patterned first conductive layer 110 may include the first voltage line VL1, the second voltage line VL2, and the light blocking pattern BML, and the first conductive layer 110 may not be formed in the pad area PDA of the non-display area NDA.

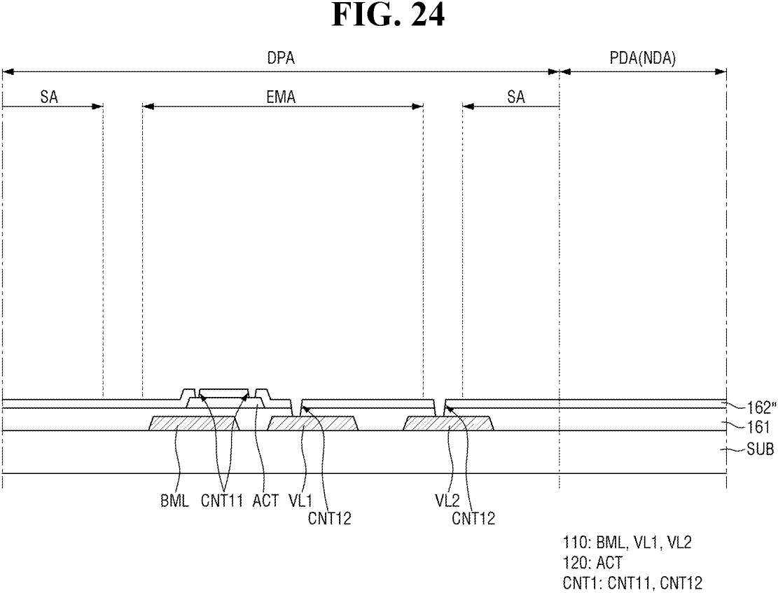

Next, referring to FIG. 24, a plurality of first contact holes CNT1 exposing the first conductive layer 110 or the semiconductor layer 120 are formed. The first contact holes CNT1 include first contact holes CNT11 exposing portions of the semiconductor layer 120 and first contact holes CNT12 exposing portions of the first conductive layer 110.

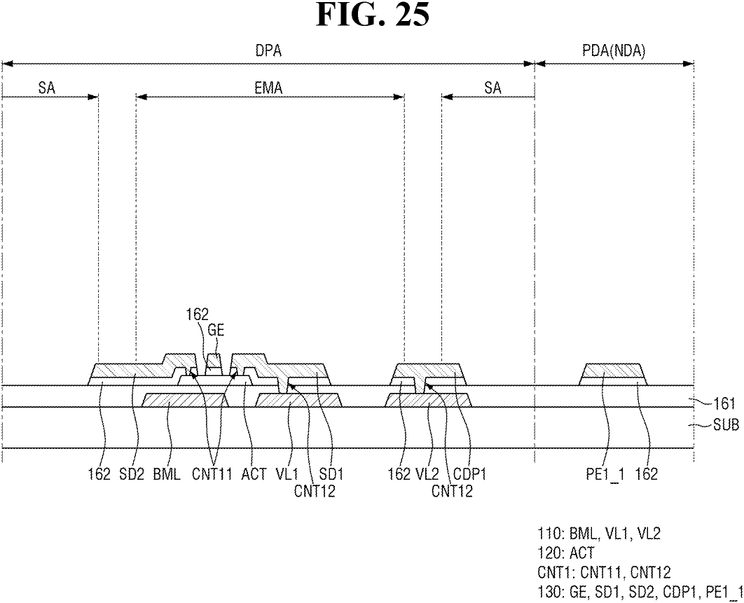

Next, referring to FIG. 25, a patterned gate insulating film 162 and a patterned second conductive layer 130 are formed on the buffer layer 161 in which the first contact holes CNT1 are formed. In one or more embodiments, the second conductive layer 130 may include the gate electrode GE, the drain electrode SD1, the source electrode SD2, and the first conductive pattern CDP1 disposed in the display area DPA and the first pad PE1_1 disposed in the pad area PDA of the non-display area NDA.

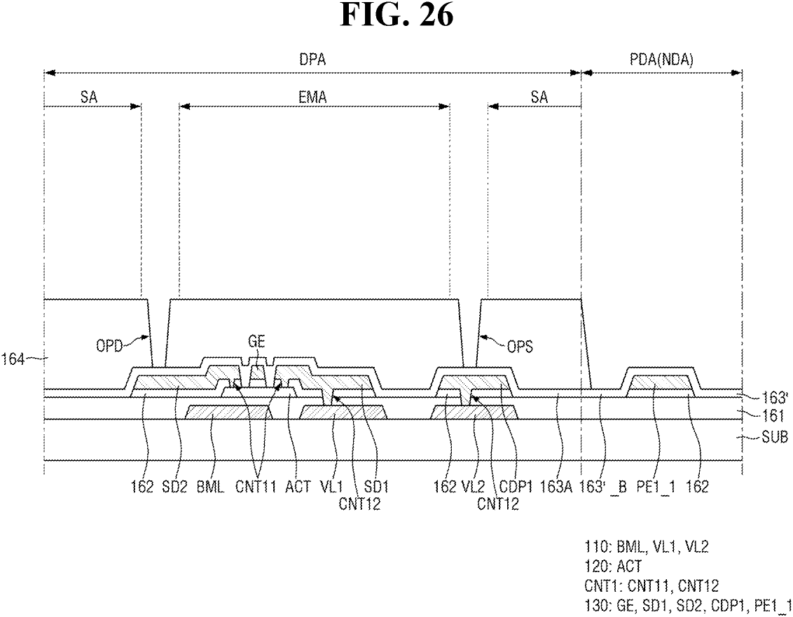

Next, referring to FIG. 26, a material layer 163' for a passivation layer is stacked on the buffer layer 161 on which the second conductive layer 130 is formed, and a patterned via layer 164 is formed.

The material layer 163' for a passivation layer may be entirely disposed over the display area DPA and the non-display area NDA, and may completely cover the patterned second conductive layer 130.

The patterned via layer 164 may be disposed in the display area DPA, but may not be disposed in the pad area PDA of the non-display area NDA. The patterned via layer 164 may be disposed in the display area DPA, and may include a first opening OPD overlapping the source electrode SD2 and a second opening OPS overlapping the first conductive pattern CDP1.

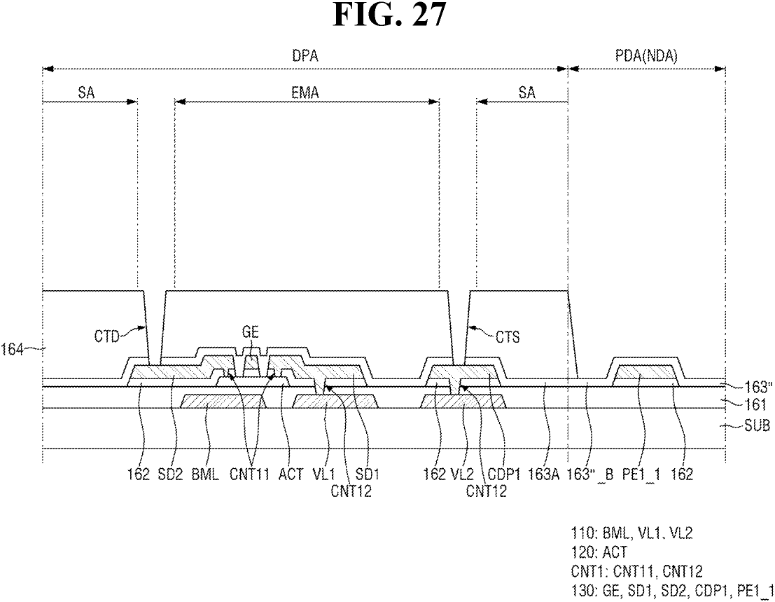

Next, referring to FIG. 27, a patterned passivation layer 163" is formed by etching the material layer 163' for a passivation layer. The patterned passivation layer 163" may be formed by a mask process.

For example, a photoresist pattern is formed on the material layer 163' for a passivation layer on which the via layer 164 of FIG. 26 is formed. The photoresist pattern may expose regions overlapping the first opening OPD and the second opening OPS of the via layer 164, and cover the material layer 163' for a passivation layer disposed in the pad area PDA of the non-display area NDA. The material layer 163' for a for a passivation layer is etched using the photoresist pattern as an etching mask. Through the process, the material layer 163' for a passivation layer exposed by the first and second openings OPD and OPS is etched, such that the first and second electrode contact holes CTD and CTS may be formed in the first area 163A of the material layer 163' disposed in the display area DPA, as illustrated in FIG. 27. In addition, the material layer 163' for a passivation layer disposed in the pad area PDA of the non-display area NDA, covered by the photoresist pattern remains, such that a second area 163"_B of the passivation layer 163'" may completely cover the first pad PE1_1, as illustrated in FIG. 27.

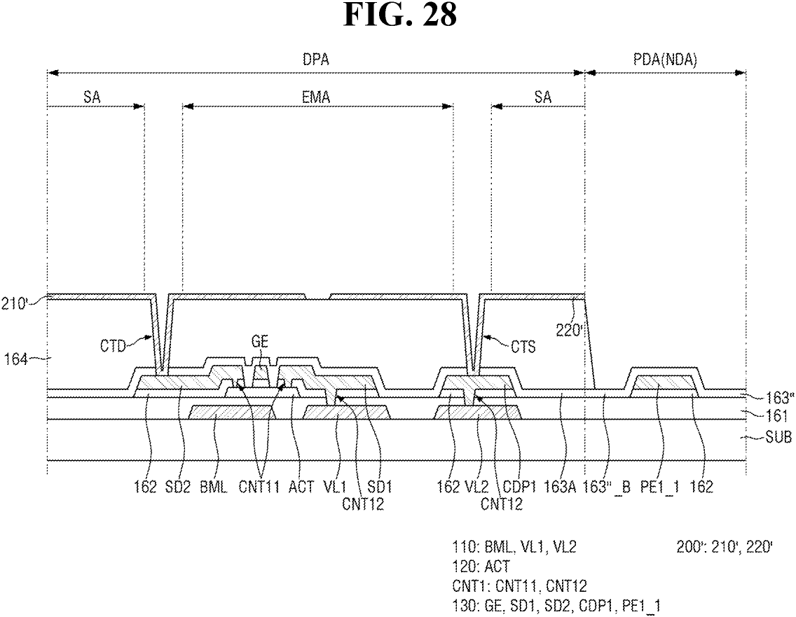

Next, referring to FIG. 28, a patterned alignment line layer 200' is formed on the via layer 164 in which the first and second electrode contact holes CTD and CTS are formed. The patterned alignment line layer 200' may be formed by a mask process.

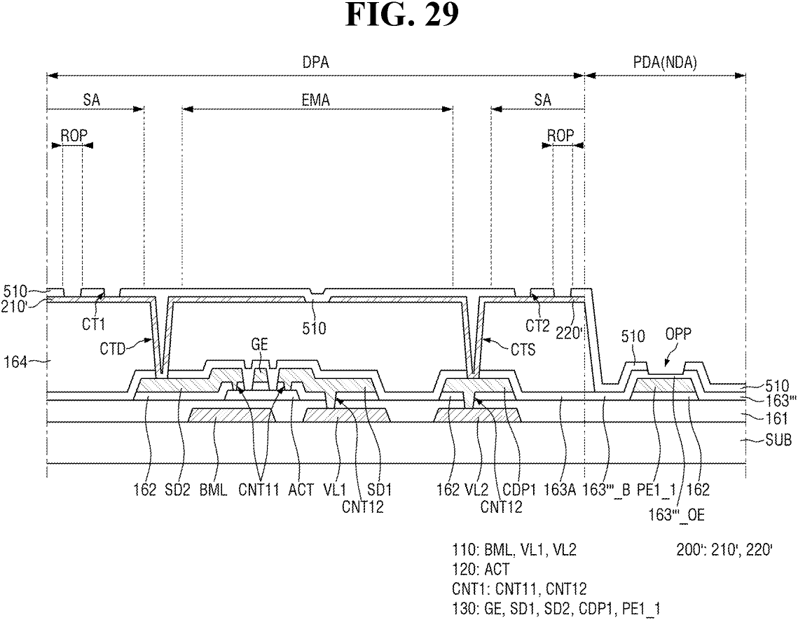

Next, referring to FIG. 29, a patterned first insulating layer 510 is formed on the alignment line layer 200'. The patterned first insulating layer 510 may be formed by a mask process.

For example, as illustrated in FIG. 29, a material layer for a first insulating layer is entirely deposited on the via layer 164 on which the patterned alignment line layer 200' is formed and the passivation layer 163". The material layer for a first insulating layer may be deposited on the via layer 164 on which the alignment line layer 200' is formed in the display area DPA, and may be disposed on the second area 163"'_B of the passivation layer 163'" in the pad area PDA of the non-display area NDA.

Next, a photoresist pattern exposing portions of the alignment line layer 200' in the display area DPA and exposing a portion of the first pad PE1_1 in the pad area PDA of the non-display area NDA may be formed on the material layer for a first insulating layer, and the material layer for a first insulating layer may be etched using the photoresist pattern as an etching mask to form the patterned first insulating layer 510 as illustrated in FIG. 29.

The patterned first insulating layer 510 may include a separation part ROP, a first contact part CT1, and a second contact part CT2 that are disposed in the sub-area SA and expose portions of the alignment line layer 200', in the display area DPA. In addition, the patterned first insulating layer 510 may include a first pad opening OPP overlapping the first pad PE1_1 in the pad area PDA.

Meanwhile, in the process of forming the patterned first insulating layer 510, a partial region 163"'_OE of a passivation layer 163'" disposed in the pad area PDA and overlapping the first pad opening OPP may be overetched as illustrated in FIG. 29. Accordingly, a thickness of the partial region 163"'_OE of the passivation layer 163'" overlapping the first pad opening OPP may be reduced.

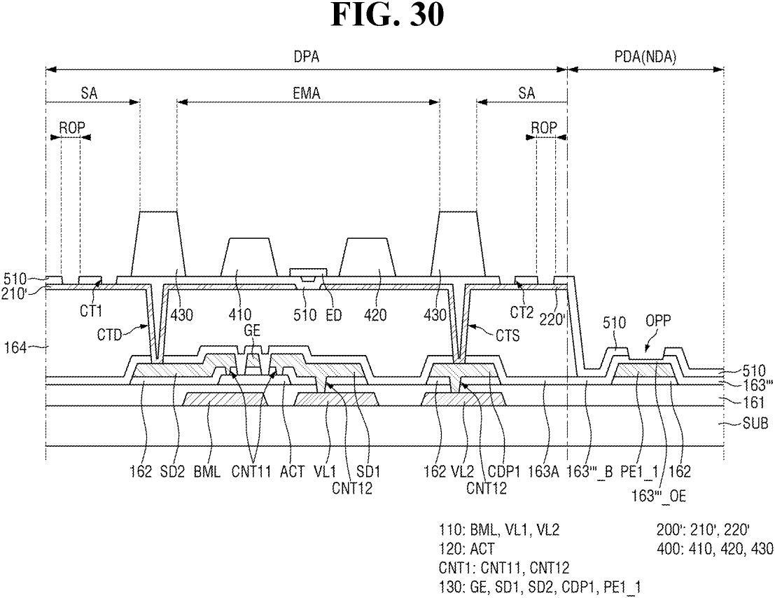

Next, referring to FIG. 30, a patterned bank layer 400 is formed on the first insulating layer 510, and the light emitting element ED is disposed in the emission area EMA of the display area DPA.

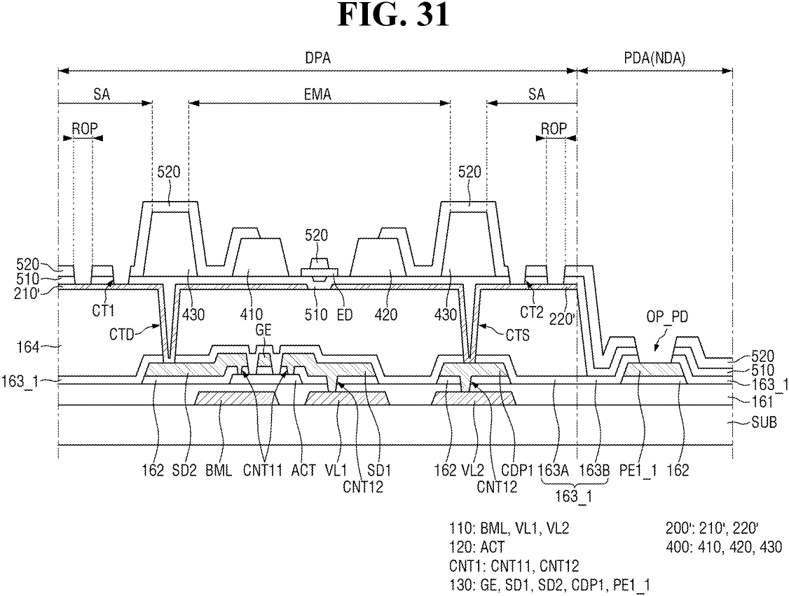

Next, referring to FIG. 31, a patterned second insulating layer 520 is formed on the first insulating layer 510 on which the light emitting element ED and the bank layer 400 are disposed. The patterned second insulating layer 520 may be formed by a mask process.

The patterned second insulating layer 520 may include a separation part ROP, a first contact part CT1, and a second contact part CT2 that are disposed in the sub-area SA and expose portions of the alignment line layer 200', in the display area DPA. The patterned second insulating layer 520 may include a pattern part exposing both ends of the light emitting element ED disposed in the emission area EMA in the display area DPA. The pattern part may be disposed on the light emitting element ED and expose both ends of the light emitting element ED.

In addition, the patterned second insulating layer 520 may define the pad opening OP_PD overlapping the first pad PE1_1 in the pad area PDA. Meanwhile, in the process of forming the patterned second insulating layer 520, the partial region 163"'_OE (see FIG. 30) of the passivation layer 163'" disposed in the pad area PDA and overlapping the pad opening OP_PD may be overetched to expose an upper surface of the first pad PE1_1. Therefore, the pad opening OP_PD penetrating through the second insulating layer 520, the first insulating layer 510, and the passivation layer 163_1 and exposing the first pad PE1_1 may be formed in the pad area PDA.

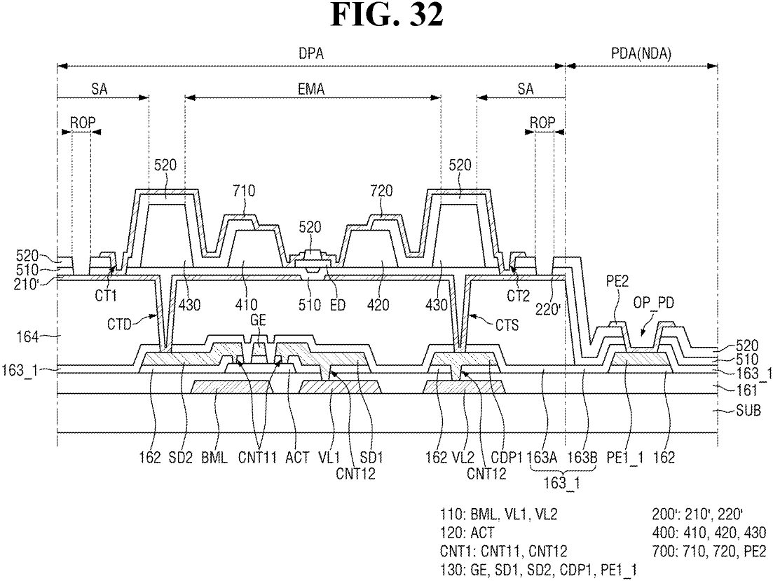

Next, referring to FIG. 32, a patterned second layer 700 is formed on the second insulating layer 520. Through the process, the first contact electrode 710 may also be deposited on an inner portion of the first contact part CT1 to be in contact with and electrically connected to a portion of the first alignment line 210' and the second contact electrode 720 may also be deposited on an inner portion of the second contact part CT2 to be in contact with and electrically connected to a portion of the second alignment line 220'. In addition, the pad electrode PE2 may also be deposited on an inner portion of the pad opening OP_PD to be in contact with and electrically connected to the first pad PE1_1 of the second conductive layer 130.

Next, referring to FIGS. 32 and 22, the first electrode 210 and the second electrode 220 separated in the separation part ROP as illustrated in FIG. 22 are formed by cutting the alignment line layer 200' overlapping the separation part ROP. Through the cutting process, the alignment line layer 200' overlapping the separation part ROP may be removed to expose one surface of the via layer 164.

With the processes of manufacturing the display device 10 according to one or more embodiments, the number of masks may be reduced by forming the plurality of wirings using the first conductive layer 110 and the second conductive layer 130 and electrically connecting the semiconductor layer 120 and the first conductive layer 110 to each other through the second conductive layer 130.

In addition, the wiring pad WPD and the pad electrode PE2 having excellent reliability may be formed by forming the first pad PE1_1 using the second conductive layer 130. For example, a process of patterning the first insulating layer 510 or the second insulating layer 520 is performed in a state in which the second conductive layer 130 disposed in the pad area PDA is covered by the passivation layer 163 before the process of patterning the first insulating layer 510 or the second insulating layer 520, and thus, direct contact between the first pad PE1_1 and a chemical material (e.g., an etchant or a material layer) used in the process of patterning the first insulating layer 510 or the second insulating layer 520 may be reduced or prevented to reduce or prevent the likelihood of the first pad PE1_1 being damaged.

Meanwhile, the first pad PE1_1 is formed using the second conductive layer 130, and thus, a mask process for forming the passivation layer 163_1 may be added in order to protect the second conductive layer 130 using the passivation layer 163_1. Accordingly, in a case of the processes of manufacturing the display device 10 according to one or more embodiments, efficiency of the processes of manufacturing the display device 10 may be reduced, but the display device 10 may include the first pad PE1_1 formed of the second conductive layer 130 and having improved reliability.

In addition, a structure in which the second layer 700 and the second conductive layer 130 may be in direct contact with and electrically connected to each other may be implemented without disposing an additional connection pattern between the second layer 700 and the second conductive layer 130. Accordingly, the display device 10 may be manufactured without additionally designing a connection pattern connecting the second layer 700 and the second conductive layer 130 to each other, and thus, a design space of the display device 10 is additionally secured, such that a design of the display device 10 may be easy.

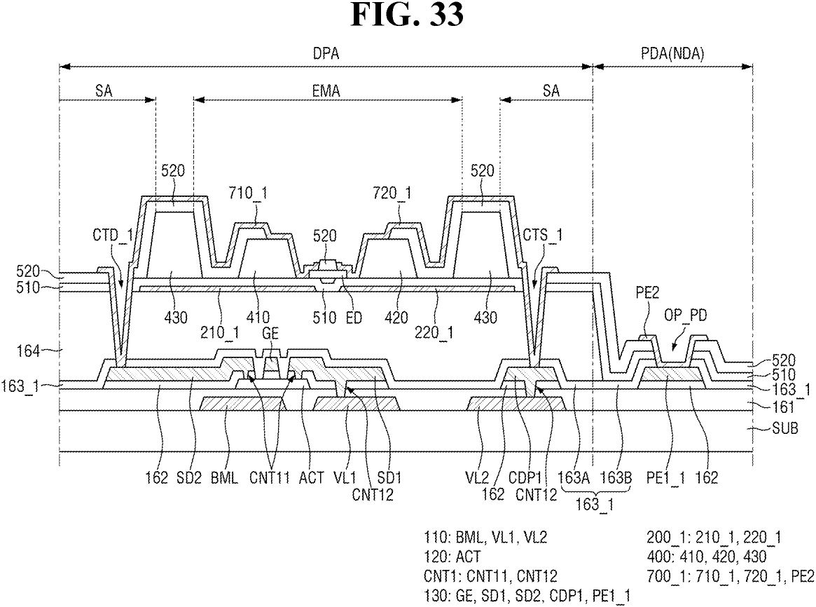

FIG. 33 is a cross-sectional view of a display device according to still one or more other embodiments.

Referring to FIG. 33, a display device 10 according to one or more embodiments is different from the display device according to still one or more other embodiments of FIG. 22 in that a first contact electrode 710_1 included in a second layer 700_1 is in direct contact with and electrically connected to the source electrode SD2 included in the second conductive layer 130 and a second contact electrode 720_1 included in the second layer 700_1 is in direct contact with and electrically connected to the first conductive pattern CDP1 included in the second conductive layer 130, in the display area DPA.

For example, the first contact electrode 710_1 may be in contact with and electrically connected to the source electrode SD2 exposed by a first electrode contact hole CTD_1 penetrating through the first area 163A of the passivation layer 163_1, the via layer 164, the first insulating layer 510, and the second insulating layer 520 that are disposed in the display area DPA. The first contact electrode 710_1 may not be in direct contact with a first electrode 210_1.

The second contact electrode 720_1 may be in contact with and electrically connected to the first conductive pattern CDP1 exposed by a second electrode contact hole CTS_1 penetrating through the first area 163A of the passivation layer 163_1, the via layer 164, the first insulating layer 510, and the second insulating layer 520 that are disposed in the display area DPA. The second contact electrode 720_1 may not be in direct contact with a second electrode 220_1.

Meanwhile, in one or more embodiments, the first electrode 210_1 and the second electrode 220_1 of a first layer 200_1 may be used in a process of aligning the light emitting elements ED, and a process of bringing the first electrode 210_1 and the second electrode 220_1 of the first layer 200_1 into contact with the first contact electrode 710_1 and the second contact electrode 720_1 of the second layer 700_1, respectively, may be omitted. In one or more embodiments, the first and second contact electrodes 710_1 and 720_1 of the second layer 700_1 and the second conductive layer 130 are in direct contact with and connected to each other also in the display area DPA without an additional connection pattern connecting the second layer 700_1 and the second conductive layer 130 to each other, and thus, a design space is secured, such that a design of the display device 10 may be easy.

In one or more embodiments, a process of forming the first and second electrode contact holes CTD_1 and CTS_1 connecting the second layer 700 and the second conductive layer 130 to each other in the display area DPA may be performed in the same manner as a process of forming the pad opening OP_PD in the pad area PDA. For example, a process of forming the first and second insulating layers 510 and 520 is performed in a state in which the passivation layer 163_1 covers the source electrode SD2 and the first conductive pattern CDP1 of the second conductive layer 130 before the process of forming the first and second insulating layers 510 and 520, and in the process of forming the first and second insulating layers 510 and 520, the passivation layer 163_1 may be overetched to form the first and second electrode contact holes CTD_1 and CTS_1 as illustrated in FIG. 33.

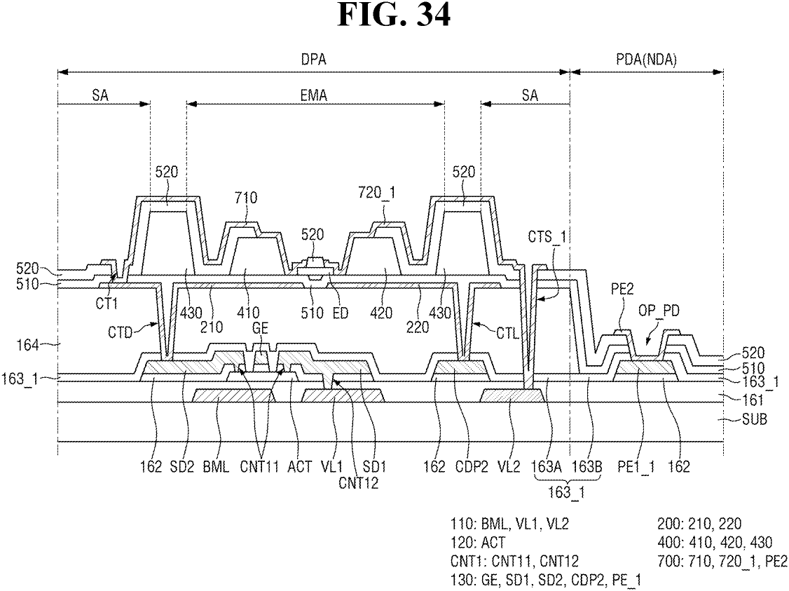

FIG. 34 is a cross-sectional view of a display device according to still one or more other embodiments.

Referring to FIG. 34, a display device 10 according to one or more embodiments is different from the display device according to still one or more other embodiments of FIG. 22 in that a passivation layer 163_1 is also disposed in the pad area PDA of the non-display area NDA and a first pad PE1_1 is formed of the second conductive layer 30.

A process of forming a second electrode contact hole CTS_1 connecting a second contact electrode 720_1 and the second voltage line VL2 of the first conductive layer 110 to each other may include forming the buffer layer 161 so as to cover the second voltage line VL2 and forming a patterned via layer 164 overlapping the second voltage line VL2 covered by the buffer layer 161 but exposing the buffer layer 161. Next, the buffer layer 161 overlapping the second voltage line VL2 may be exposed through a process of patterning the passivation layer 163_1 using the patterned via layer 164. Next, a portion of the buffer layer 161 exposed by the via layer 164 and the passivation layer 163_1 may be overetched in a process of patterning the first insulating layer 510. Next, the buffer layer 161 remaining in the process of patterning the first insulating layer 510 may be overetched in a process of patterning the second insulating layer 520 to form the second electrode contact hole CTS_1 penetrating through the second insulating layer 520, the first insulating layer 510, the via layer 164, the passivation layer 163_1, and the buffer layer 161 and exposing the second voltage line VL2 of the first conductive layer 110.

Accordingly, in the display area DPA, the second layer 700 and the first conductive layer 110 may be in direct contact with and electrically connected to each other, and in the pad area PDA, the second layer 700 and the second conductive layer 130 may be in direct contact with and electrically connected to each other. Meanwhile, a connection relationship between the first conductive layer 110 and the second layer 700 illustrated in FIG. 34 may be only an example. As another example, the source electrode SD2 may be formed of the first conductive layer 110, and the source electrode SD2 and the first contact electrode 710 of the second layer 700 may also be directly connected to each other.

In concluding the detailed description, those skilled in the art will appreciate that many variations and modifications can be made to the embodiments without substantially departing from the principles of the present disclosure. Therefore, the disclosed embodiments of the present disclosure are used in a generic and descriptive sense only and not for purposes of limitation.

What is claimed is:

1. A display device comprising:
a substrate including a display area and a pad area;
a first conductive layer disposed on the substrate and including a first signal line disposed in the display area;
a buffer layer disposed on the first conductive layer;
a semiconductor layer disposed on the buffer layer in the display area;
a gate insulating film disposed on the semiconductor layer;
a second conductive layer disposed on the gate insulating film and including a gate electrode overlapping the semiconductor layer in the display area, a first electrode of a transistor disposed to overlap one side of the semiconductor layer in the display area and connected to the first signal line through a contact hole penetrating through the buffer layer and the gate insulating film, and a second electrode of the transistor disposed to overlap the other side of the semiconductor layer in the display area;
a first pad disposed on the buffer layer in the pad area and exposed by a pad opening;
a first insulating layer disposed on the second conductive layer and the first pad; and
a light emitting element disposed on the first insulating layer in the display area,
wherein the first pad is formed of the first conductive layer or the second conductive layer.

2. The display device of claim 1, further comprising:
a passivation layer disposed on the second conductive layer and the first pad;
a via layer disposed on the passivation layer; and
a first electrode and a second electrode disposed on the via layer in the display area and spaced apart from each other,
wherein the first insulating layer is disposed on the first electrode and the second electrode, the light emitting element is disposed between the first electrode and the second electrode on the first insulating layer, and the pad opening is defined by the first insulating layer.

3. The display device of claim 2, wherein the first pad is formed of the first conductive layer, the pad opening is defined by the first insulating layer and the buffer layer, and sidewalls of the first insulating layer and the buffer layer defining the pad opening are aligned with each other.

4. The display device of claim 3, wherein the passivation layer and the via layer are not disposed in the pad area.

5. The display device of claim 3, wherein sidewalls of the via layer and sidewalls of the passivation layer are aligned with each other.

6. The display device of claim 2, wherein the first pad is formed of the second conductive layer, the pad opening is defined by the first insulating layer and the passivation layer, and sidewalls of the first insulating layer and the passivation layer defining the pad opening are aligned with each other.

7. The display device of claim 6, wherein the passivation layer includes a first area disposed in the display area and overlapping the via layer, and a second area disposed in the pad area and exposed by the via layer.

8. The display device of claim 2, wherein the first electrode of the transistor is covered by the passivation layer and the via layer, and the second electrode of the transistor is exposed by a first electrode contact hole penetrating through the passivation layer and the via layer.

9. The display device of claim 8, wherein the first electrode is in contact with and electrically connected to the second electrode of the transistor through the first electrode contact hole.

10. The display device of claim 9, further comprising a first contact electrode in contact with one end of the light emitting element and the first electrode exposed by the first insulating layer.

11. The display device of claim 8, further comprising a first contact electrode in contact with one end of the light emitting element, wherein the first contact electrode is in contact with and electrically connected to the second electrode of the transistor through the first electrode contact hole.

12. The display device of claim 11, wherein the first pad is formed of the second conductive layer.

13. The display device of claim 1, further comprising:
a first contact electrode disposed on the light emitting element in the display area and in contact with one end of the light emitting element;
a second contact electrode disposed on the light emitting element in the display area and in contact with the other end of the light emitting element; and
a pad electrode disposed on the first insulating layer in the pad area and in contact with the first pad exposed by the pad opening.

14. The display device of claim 13, wherein the first conductive layer further includes a second signal line disposed in the display area, and the second contact electrode is electrically connected to the second signal line.

15. The display device of claim 14, wherein the second conductive layer further includes a first conductive pattern disposed to overlap the second signal line in the display area and connected to the second signal line through a contact hole penetrating through the buffer layer and the gate insulating film, the second electrode is in contact with the first conductive pattern, and the second contact electrode is in contact with the second electrode exposed by the first insulating layer.

16. The display device of claim 14, wherein the second contact electrode is in contact with the second signal line exposed by the first insulating layer and the buffer layer.

17. The display device of claim 13, wherein the first contact electrode, the second contact electrode, and the pad electrode are formed on the same layer.

18. A display device comprising:
a substrate including a display area and a pad area;
a first conductive layer disposed on the substrate and including a first signal line disposed in the display area and a first pad disposed in the pad area;
a buffer layer disposed on the first conductive layer;
a semiconductor layer disposed on the buffer layer in the display area;
a gate insulating film disposed on the semiconductor layer;
a second conductive layer disposed on the gate insulating film and including a gate electrode overlapping the semiconductor layer in the display area, a first electrode of a transistor disposed to overlap one side of the semiconductor layer in the display area, and a second electrode of the transistor disposed to overlap the other side of the semiconductor layer in the display area;
a first insulating layer disposed on the second conductive layer;
a light emitting element disposed on the first insulating layer in the display area;
a first contact electrode disposed in the display area and electrically connecting the transistor, the first electrode, and one end of the light emitting element to each other; and
a pad electrode disposed in the pad area and electrically connected to the first pad through a pad opening penetrating through the buffer layer and the first insulating layer,
wherein the first electrode of the transistor is electrically connected to the first signal line through a contact hole penetrating through the buffer layer and the gate insulating film.

19. The display device of claim 18, wherein the first contact electrode and the pad electrode are formed on the same layer.

20. The display device of claim 18, wherein sidewalls of the buffer layer and the first insulating layer defining the pad opening are aligned with each other.
